(19) United States
(12) Patent Application Publication
(10) Pub. No.: US 2020/0006670 A1
(43) Pub. Date: Jan. 2, 2020

(54) CHIRAL ORGANIC LIGAND, CHIRAL COMPLEX SUPRAMOLECULAR BODY AND ORGANIC ELECTRONIC DEVICE INCLUDING THE SAME

(71) Applicant: POSTECH ACADEMY-INDUSTRY FOUNDATION, Pohang-si (KR)

(72) Inventors: Joon Hak OH, Seoul (KR); Xiaobo SHANG, Seoul (KR); Inho SONG, Seoul (KR)

(21) Appl. No.: 16/272,969

(22) Filed: Feb. 11, 2019

(30) Foreign Application Priority Data
Jun. 27, 2018 (KR) 10-2018-0073789
Dec. 7, 2018 (KR) 10-2018-0157410

(51) Int. Cl. H01L 51/00

(52) U.S. Cl. CPC H01L 51/0072; H01L 51/0083; C09K 11/06; C09K 2211/1044; H01L 51/0084

(57) ABSTRACT

A chiral organic ligand according to an exemplary embodiment is any one selected from the group consisting of organic ligands represented by the following Chemical Formula 1 and Chemical Formula 2:

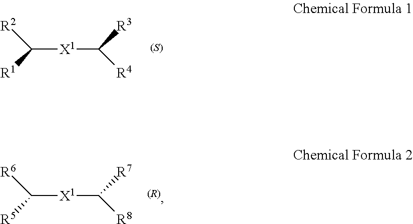

wherein
X1 and X2 independently of each other

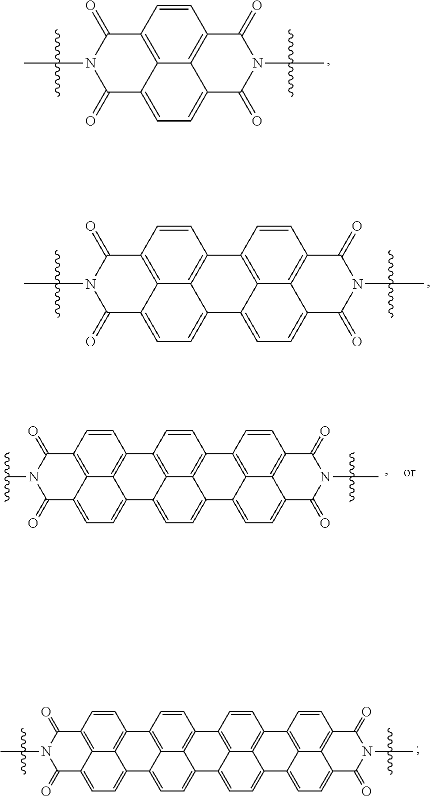 [SMILES: *N1C(=O)c2ccc3c4c(ccc(c24)C1=O)C(=O)N(*)C3=O ; *N1C(=O)c2ccc3c4ccc5c6c(ccc(c7ccc(c2c37)C1=O)c64)C(=O)N(*)C5=O ; *N1C(=O)c2ccc3c4ccc5c6ccc7c8c(ccc(c9ccc(c%10ccc(c2c3%10)C1=O)c4c59)c86)C(=O)N(*)C7=O ; *N1C(=O)c2ccc3c4ccc5c6ccc7c8ccc9c%10c(ccc(c%11ccc(c%12ccc(c%13ccc(c2c3%13)C1=O)c4c5%12)c6c7%11)c%108)C(=O)N(*)C9=O]

R1, R3, R5, and R7 are independently of one another any one selected from the group consisting of a carboxy group, a hydroxyl group, an amino group, a sulfhydryl group, and a phosphate; and R2, R4, R6, and R8 are independently of one another any one selected from the group consisting of C1 to C5 alkyl groups and C1 to C5 aryl groups.

### TECHNICAL FIELD

The present invention relates to a chiral organic ligand, chiral complex supramolecular body, and an organic electronic device including the same. More particularly, the present invention relates to a chiral organic ligand, chiral complex supramolecular body, and an organic electronic device including the same, wherein a metal is coordinated with a chiral organic ligand to prepare a chiral complex supramolecular body, thereby securing supramolecular chirality, and being applicable as various chirality-based sensors for detecting a chiral element.

### BACKGROUND ART

Most of amino acids, sugars, enzymes, and the like which are present in nature have chirality, and accordingly, a medicine may be also manufactured in the form of an enantiomer having chirality. One of paired enantiomers is used as a medicine, but the other one may have a potential side effects, and thus, a technique to separate and detect the enantiomers is greatly spotlighted.

### DISCLOSURE

### Technical Problem

The present invention has been made in an effort to provide a chiral complex supramolecular body having supramolecular chirality and a manufacturing method thereof, by preparing an organic ligand having chirality and coordinating the organic ligand with a metal.

In addition, the present invention has been made in an effort to provide an organic electronic device which can detect various elements (light, chemical gas, and the like) with high performance, by manufacturing an organic electronic device including the chiral complex supramolecular body, and a manufacturing method thereof.

### Technical Solution

An exemplary embodiment of the present invention provides a chiral organic ligand which is any one selected from the group consisting of organic ligands represented by the following Chemical Formula 1 and Chemical Formula 2:

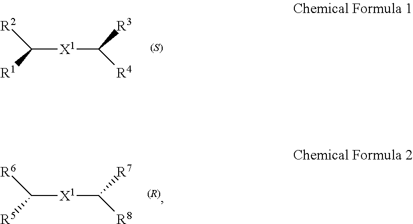

wherein

X¹ and X² are independently of each other

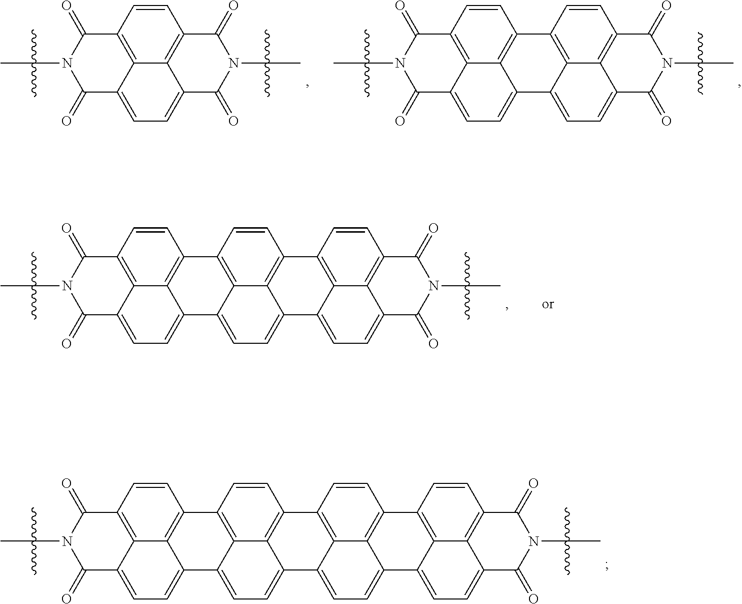

R¹, R³, R⁵, and R⁷ are independently of one another any one selected from the group consisting of a carboxy group, a hydroxyl group, an amino group, a sulfhydryl group, and a phosphate; and R², R⁴, R⁶, and R⁸ are independently of one another any one selected from the group consisting of C1 to C5 alkyl groups and C1 to C5 aryl groups.

R¹, R³, R⁵, and R⁷ may be independently of one another any one selected from the group consisting of a carboxy group, a hydroxyl group, and an amino group; and R², R⁴, R⁶, and R⁸ may be independently of one another any one selected from the group consisting of C1 to C3 alkyl groups and C1 to C3 aryl groups.

R¹, R³, R⁵, and R⁷ may be a carboxy group, and R², R⁴, R⁶, and R⁸ may be a methyl group.

Another embodiment of the present invention provides a chiral complex supramolecular body including: a chiral organic ligand which is any one selected from the group consisting of organic ligands represented by the following Chemical Formula 1 and Chemical Formula 2; and a metal ion coordinated with the organic ligand, wherein the metal ion coordinated with the organic ligand is any one selected from the group consisting of zinc, copper, nickel, cadmium, iron, chromium, cobalt, calcium, magnesium, manganese, silver, and gold:

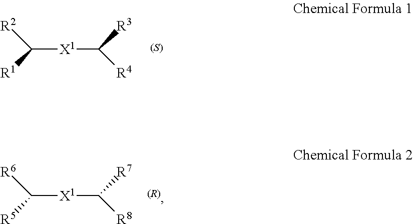

wherein

X¹ and X² are independently of each other

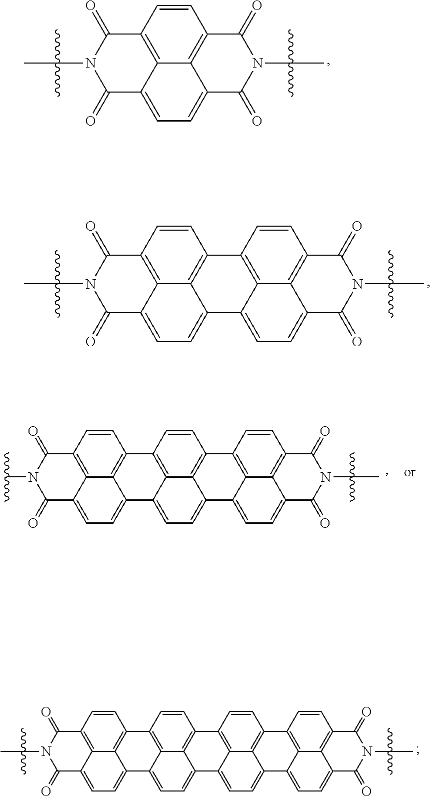 [SMILES: *N1C(=O)c2ccc3c4c(ccc(c24)C1=O)C(=O)N(*)C3=O ; *N1C(=O)c2ccc3c4ccc5c6c(ccc(c7ccc(c2c37)C1=O)c64)C(=O)N(*)C5=O ; *N1C(=O)c2ccc3c4ccc5c6ccc7c8c(ccc(c9ccc(c%10ccc(c2c3%10)C1=O)c4c59)c86)C(=O)N(*)C7=O ; *N1C(=O)c2ccc3c4ccc5c6ccc7c8ccc9c%10c(ccc(c%11ccc(c%12ccc(c%13ccc(c2c3%13)C1=O)c4c5%12)c6c7%11)c%108)C(=O)N(*)C9=O]

R¹, R³, R⁵, and R⁷ are independently of one another any one selected from the group consisting of a carboxy group, a hydroxyl group, an amino group, a sulfhydryl group, and a phosphate; and R², R⁴, R⁶, and R⁸ are independently of one another any one selected from the group consisting of C1 to C5 alkyl groups and C1 to C5 aryl groups.

A single crystal of the chiral complex supramolecular body may have a ribbon shape.

Another embodiment of the present invention provides an organic electronic device including a substrate; an electrode disposed on the substrate; and an active layer including a chiral complex supramolecular body, disposed on the electrode, wherein the chiral complex supramolecular body includes: a chiral organic ligand which is any one selected from the group consisting of organic ligands represented by the following Chemical Formula 1 and Chemical Formula 2; and a metal ion coordinated with the organic ligand, and the metal ion is any one selected from the group consisting of zinc, copper, nickel, cadmium, iron, chromium, cobalt, calcium, magnesium, manganese, silver, and gold:

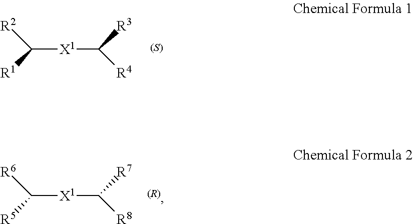

wherein

X¹ and X² are independently of each other

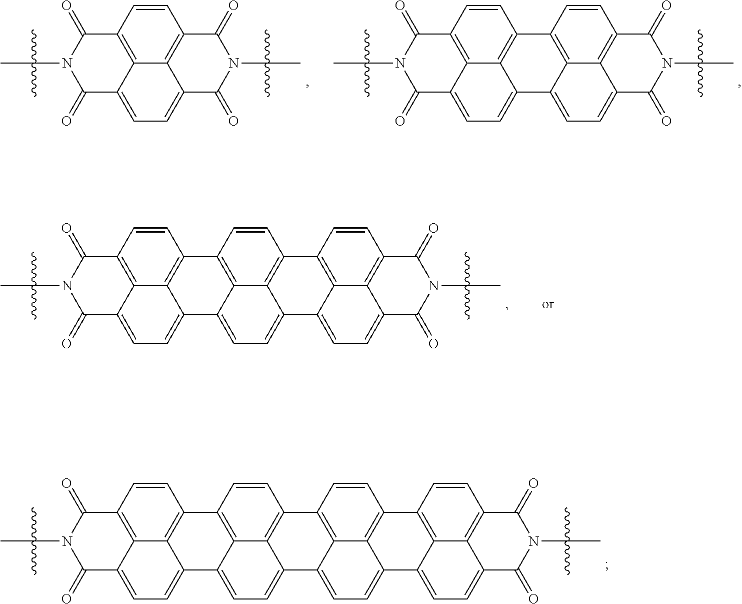

R¹, R³, R⁵, and R⁷ are independently of one another any one selected from the group consisting of a carboxy group, a hydroxyl group, an amino group, a sulfhydryl group, and a phosphate; and R², R⁴, R⁶, and R⁸ are independently of one another any one selected from the group consisting of C1 to C5 alkyl groups and C1 to C5 aryl groups.

The electrode may include a first electrode and a second electrode, and the active layer may be disposed to cross the first electrode and second electrode.

A surface modified layer disposed between the substrate and the active layer may be further included, the surface modified layer may include a self-assembled monolayer (SAM), and the self-assembled monolayer (SAM) may be formed by surface-treating the substrate with any one selected from the group consisting of n-octadecyltrimethoxysilane, n-octadecyltrichlorosilane, n-octyltrichlorosilane, n-octylphosphate, and n-octadecylphosphate.

The organic electronic device may be one selected from the group consisting of an organic sensor, an organic transistor, an organic light emitting diode, and an organic solar cell.

The organic electronic device may be an organic sensor, and the organic sensor may detect one or more selected from the group consisting of light, chemical gas, and a medicine.

As a concentration of the light, the chemical gas, or the medicine is increased, the organic sensor may have decreased luminescence intensity by photoluminescence (PL).

The luminescence by photoluminescence (PL) may be fluorescence.

The medicine may include naproxen, and as a concentration of the naproxen is increased, luminescence intensity by photoluminescence (PL) may be decreased.

The medicine may include valinol, and as a concentration of the valinol is increased, luminescence intensity by photoluminescence (PL) may be decreased.

The chemical gas may include an amine compound, alcohol, and a polar solvent.

The amine compound may include at least one of hydrazine, trimethylamine (TEA), and phenylethylamine (PEA).

The chiral complex supramolecular body may have the same crystal structure before and after exposure to the chemical gas.

Yet another embodiment of the present invention provides a manufacturing method of an organic electronic device, including: (a) providing a substrate;

(b) forming an electrode on the substrate; and (c) forming an active layer including a chiral complex supramolecular body on the electrode, wherein the chiral complex supramolecular body includes: a chiral organic ligand which is any one selected from the group consisting of organic ligands represented by the following Chemical Formula 1 and Chemical Formula 2; and a metal ion coordinated with the organic ligand, wherein the metal ion is any one selected from the group consisting of zinc, copper, nickel, cadmium, iron, chromium, cobalt, calcium, magnesium, manganese, silver, and gold:

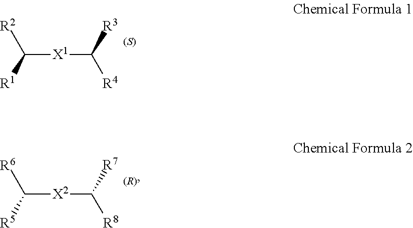

wherein

X¹ and X² are independently of each other

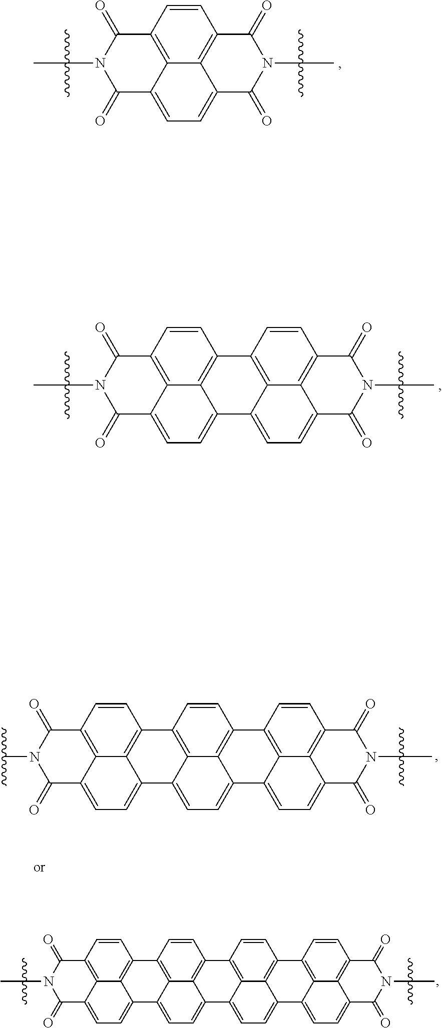 [SMILES: *N1C(=O)c2ccc3c4c(ccc(c24)C1=O)C(=O)N(*)C3=O ; *N1C(=O)c2ccc3c4ccc5c6c(ccc(c7ccc(c2c37)C1=O)c64)C(=O)N(*)C5=O ; *N1C(=O)c2ccc3c4ccc5c6ccc7c8c(ccc(c9ccc(c%10ccc(c2c3%10)C1=O)c4c59)c86)C(=O)N(*)C7=O ; *N1C(=O)c2ccc3c4ccc5c6ccc7c8ccc9c%10c(ccc(c%11ccc(c%12ccc(c%13ccc(c2c3%13)C1=O)c4c5%12)c6c7%11)c%108)C(=O)N(*)C9=O]

R¹, R³, R⁵, and R⁷ are independently of one another any one selected from the group consisting of a carboxy group, a hydroxyl group, an amino group, a sulfhydryl group, and a phosphate; and R², R⁴, R⁶, and R⁸ are independently of one another any one selected from the group consisting of C1 to C5 alkyl groups and C1 to C5 aryl groups.

After step (a), (a′) oxidation-treating one surface of the substrate to manufacture the substrate including a hydroxyl group (—OH) on the one surface may be further included.

After step (a′), (a″) forming a self-assembled monolayer (SAM) on one surface of the substrate may be further included, and the self-assembled monolayer (SAM) may be formed by, after oxidization-treating the one surface, treating the surface with any one selected from the group consisting of n-octadecyltrimethoxysilane, n-octadecyltrichlorosilane, n-octyltrichlorosilane, n-octylphosphate, and n-octadecylphosphate.

### Advantageous Effects

By coordinating a chiral organic ligand with a metal to prepare a chiral complex supramolecular body, the chiral organic ligand, the chiral complex supramolecular body, and a manufacturing method thereof according to an exemplary embodiment may secure supramolecular chirality, and minimize misarranged orientation which is disadvantageous in charge transfer, thereby greatly improving photosensitivity and electrical characteristics. In addition, a production process of a device is very simple, and may be easily applied even on a plastic substrate, thereby improving an integrated device and downsizing.

The organic electronic device and a manufacturing method thereof according to an exemplary embodiment may manufacture an organic electronic device including the chiral complex supramolecular body, thereby being applied as various chirality-based sensor devices which may detects various chiral elements (light, chemical gas, and the like) with high performance.

### DESCRIPTION OF THE DRAWINGS

FIG. 1A is a drawing illustrating a unit crystal structure of a chiral complex supramolecular body in which a (S) type chiral organic ligand is coordinated with a metal ion.

FIG. 1B is a drawing illustrating a crystal structure of a chiral complex supramolecular body in which a (S) type chiral organic ligand is coordinated with a metal ion.

FIG. 10 is a drawing illustrating a crystal structure viewed from one side of FIG. 1B.

FIG. 2A is a drawing illustrating a unit crystal structure of a chiral complex supramolecular body in which a (R) type chiral organic ligand is coordinated with a metal ion.

FIG. 2B is a drawing illustrating a crystal structure of a chiral complex supramolecular body in which a (R) type chiral organic ligand is coordinated with a metal ion.

FIG. 2C is a drawing illustrating a crystal structure viewed from one side of FIG. 2B.

FIG. 3A is a drawing illustrating a unit crystal structure of a chiral complex supramolecular body in which a racemic type chiral organic ligand is coordinated with a metal ion.

FIG. 3B is a drawing illustrating a crystal structure of a chiral complex supramolecular body in which a racemic type chiral organic ligand is coordinated with a metal ion.

FIG. 3C is a drawing illustrating a crystal structure viewed from one side of FIG. 3B.

FIG. 3D is a drawing illustrating a crystal structure of FIG. 3C to be easily understood.

FIG. 4 is a perspective view illustrating a three-dimensional schematic structure of an organic electronic device according to an exemplary embodiment.

FIG. 5 is a front view illustrating a schematic structure of an organic electronic device according to an exemplary embodiment viewed from the yz plane.

FIG. 6 is a top view illustrating a schematic structure of an organic electronic device according to an exemplary embodiment viewed from the xy plane.

FIG. 7 is a scanning electronic microscopic (SEM) image of a single crystal of a chiral complex supramolecular body according to an exemplary embodiment.

FIG. 8 is a scanning electronic microscopic (SEM) image of a portion of an organic electronic device according to an exemplary embodiment.

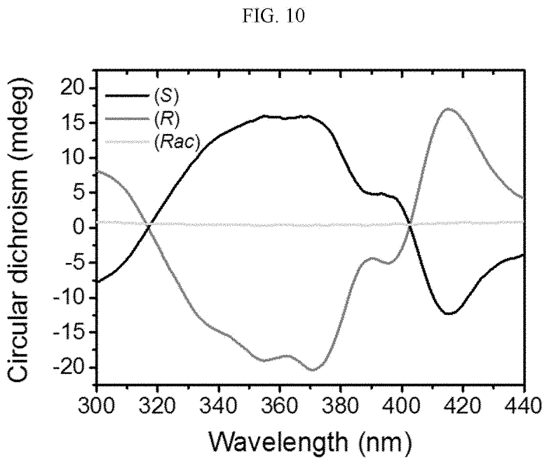

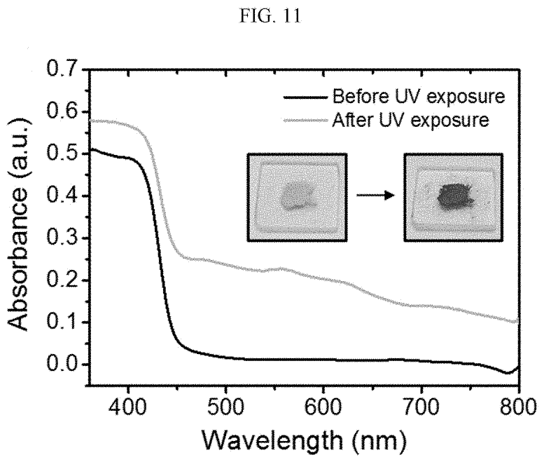

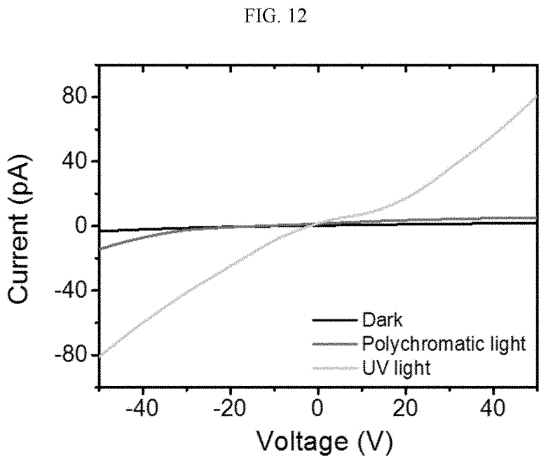

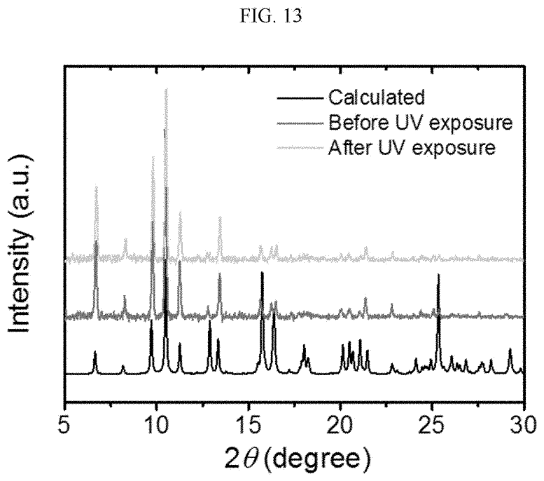

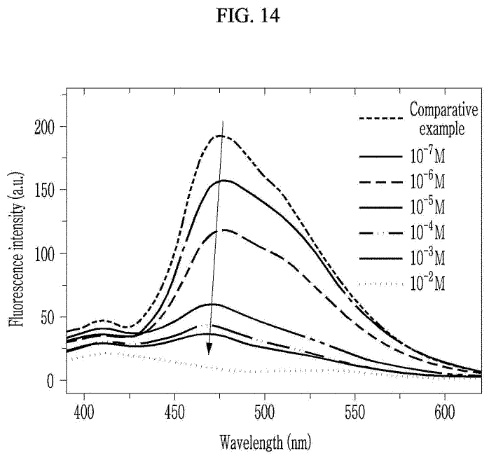

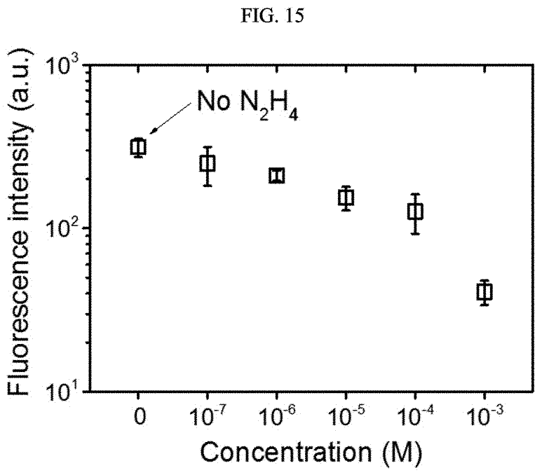

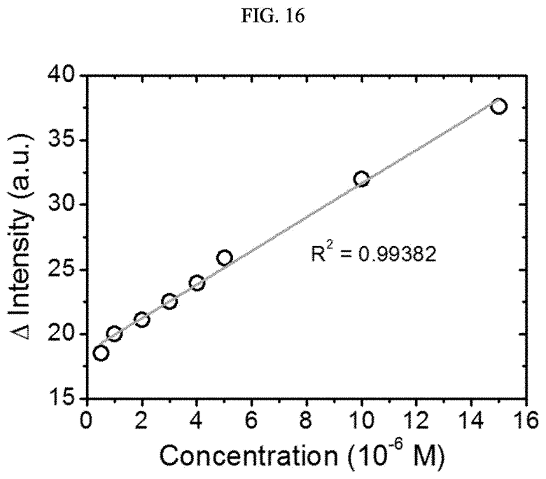

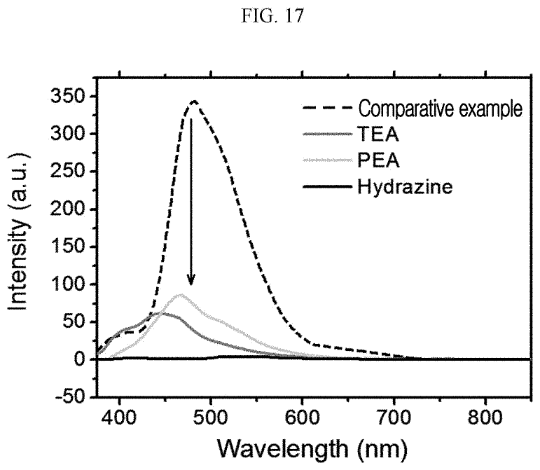

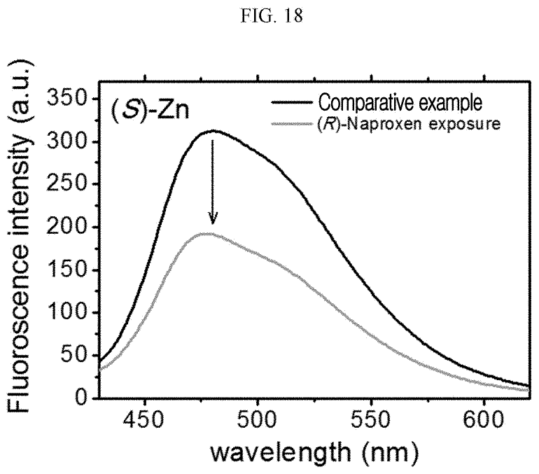

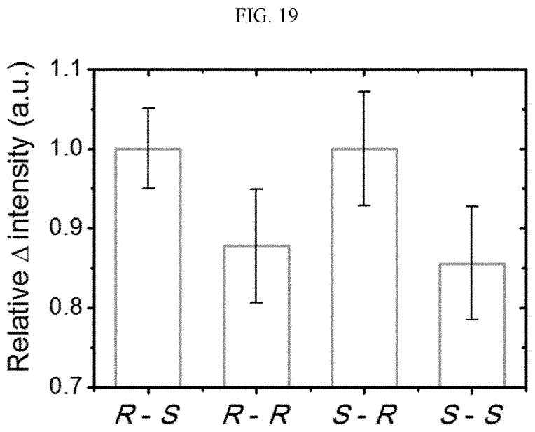

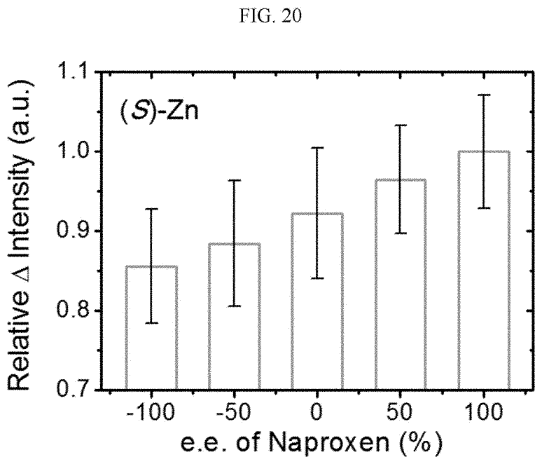

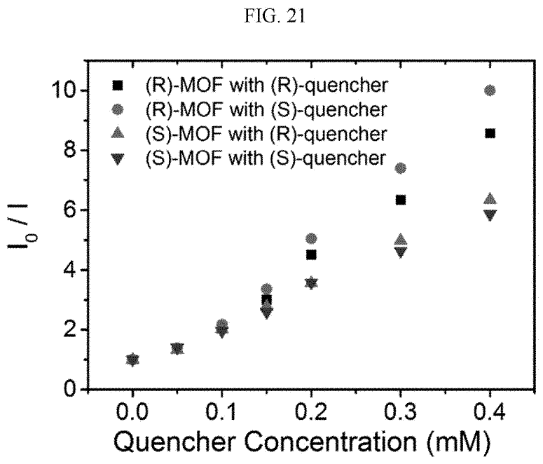

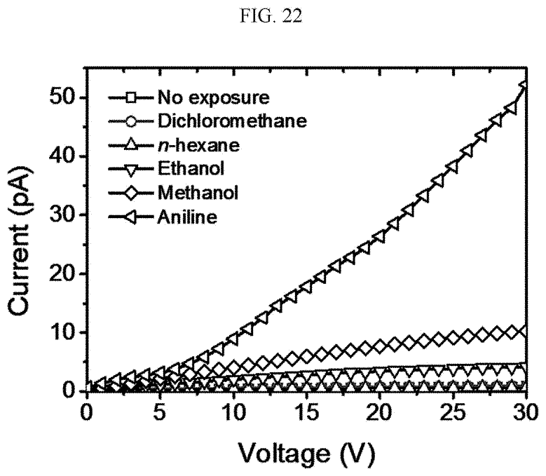

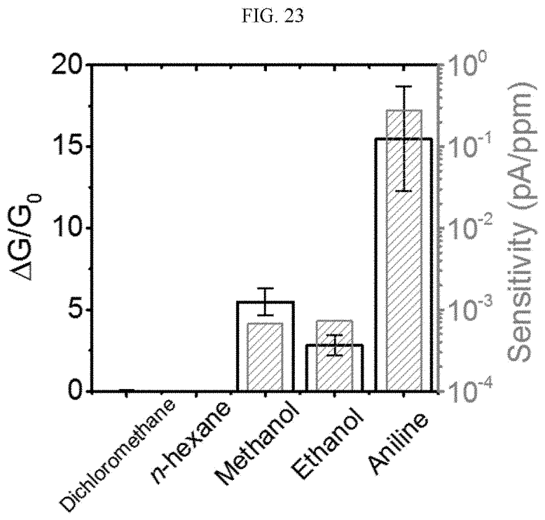

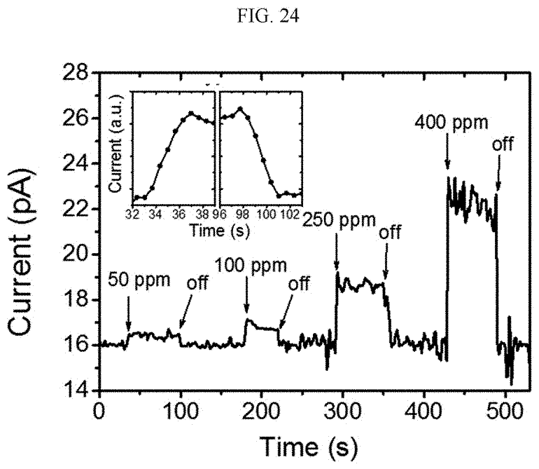

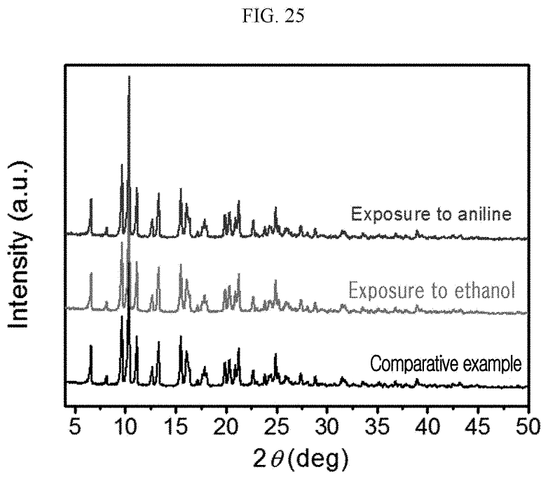

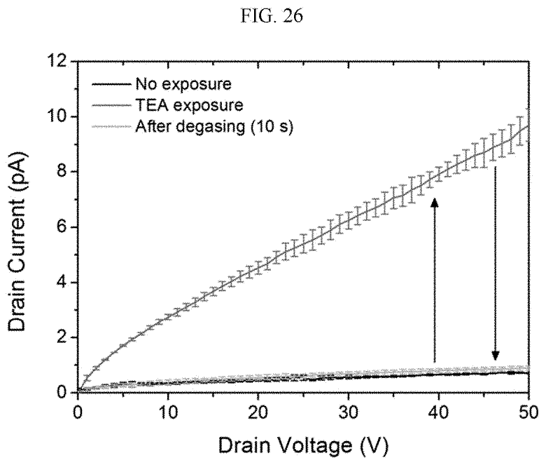

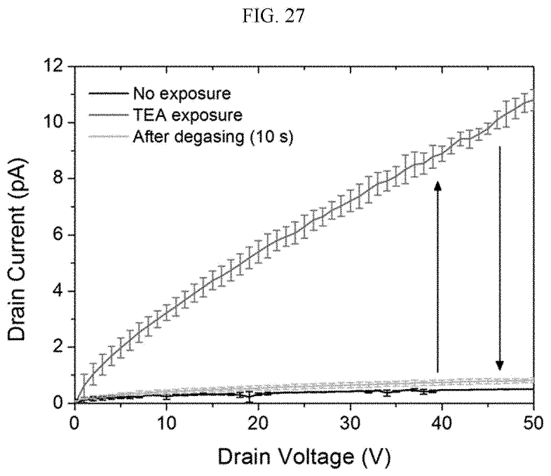

FIGS. 9 and 10 are a result of spectrum analysis of a chiral organic ligand and a chiral complex supramolecular body according to an exemplary embodiment, using circular dichroism (CD).

FIG. 11 is a graph illustrating absorbance of a chiral complex supramolecular body according to an exemplary embodiment.

FIG. 12 is a graph illustrating a current-voltage curve (I-V curve) of an organic sensor device according to an exemplary embodiment.

FIG. 13 is a graph illustrating a result of powder X-ray diffraction (PXRD) analysis before and after irradiation of ultraviolet (UV) light on a chiral complex supramolecular body according to an exemplary embodiment.

FIG. 14 is a graph illustrating luminescence intensity of a chiral complex supramolecular body according to an exemplary embodiment, depending on a wavelength for a concentration of hydrazine.

FIGS. 15 and 16 are graphs illustrating luminescence intensity of a chiral complex supramolecular body according to an exemplary embodiment, depending on a concentration of hydrazine, respectively.

FIG. 17 is a graph illustrating a sensing degree of a chiral complex supramolecular body according to an exemplary embodiment, for an amine compound (amine solution).

FIG. 18 is a graph illustrating luminescence intensity of a chiral complex supramolecular body according to an exemplary embodiment, depending on a wavelength for naproxen.

FIG. 19 is a graph illustrating a quenching degree of a chiral complex supramolecular body according to an exemplary embodiment, depending on chirality of naproxen.

FIG. 20 is a graph illustrating a quenching degree of a chiral complex supramolecular body according to an exemplary embodiment, depending on a mixing ratio of naproxen.

FIG. 21 is a graph illustrating a sensing degree of a chiral complex supramolecular body according to an exemplary embodiment, for a medicine.

FIGS. 22 and 23 are graphs illustrating electrical conductivity change and reaction sensitivity of a chiral complex supramolecular body according to an exemplary embodiment, when exposed to chemical gas, respectively.

FIG. 24 is a graph illustrating a result of real-time sensing of a chiral complex supramolecular body according to an exemplary embodiment, depending on a concentration of aniline.

FIG. 25 is a graph illustrating a result of powder X-ray diffraction (PXRD) analysis of a chiral complex supramolecular body according to an exemplary embodiment before and after adsorption of chemical gas.

FIGS. 26 and 27 are graphs illustrating a voltage-current curve for trimethylamine by organic electronic devices including a (R) type chiral complex supramolecular body and a (S) type chiral complex supramolecular body, respectively.

### MODE FOR INVENTION

Hereinafter, various exemplary embodiments of the present invention will be described in detail so that a person with ordinary skill in the art to which the present invention pertains can easily carry out the present invention, referring to accompanying drawings. The present invention may be implemented in various different forms, and is not limited to exemplary embodiments described herein.

For clearly describing the present invention, parts unrelated to description are omitted, and the same reference numeral indicates the same or like constituent element throughout the specification.

In addition, since the size and the thickness of each component shown in the drawings are optionally represented for convenience of description, the present invention is not necessarily limited to those shown in the drawing. In the drawings, the thickness is expanded for clearly expressing various layers and regions. Also in the drawing, the thicknesses of some layers and regions are exaggerated for convenience of description.

In addition, when an element such as a layer, film, region or a plate is referred to as being “over” or “on” another element, the element may be “directly on” another element, and also there may be an intervening element between the two elements. In contrast, when an element is referred to as being “directly on” another element, there are no intervening elements present.

In addition, being “over” or “on” a reference element is understood to be “on” or “under” the reference element, but is not understood to be necessarily “on” or “over” in an opposite direction of gravity.

In addition, throughout the specification, a part “comprising” an element is understood to further include the stated element, not to exclude any other element, unless explicitly described to the contrary.

In addition, throughout the specification, referring to “on a plane” means when an object is viewed from above, and referring to “on a section” means when a section of a vertically cut object is viewed from the side. An alkyl group may be a saturated alkyl group having no double bond or triple bond. An alkyl group may be an unsaturated alkyl group having at least one double bond or triple bond.

Whether the alkyl group is saturated or unsaturated, the alkyl group may be branched, linear, or cyclic.

The alkyl group may be a C1 to C30 alkyl group. More specifically, the alkyl group may be a C1 to C20 alkyl group, a C1 to C10 alkyl group, or a C1 to C6 alkyl group. For example, a C1 to C4 alkyl group has 1 to 4 carbon atoms on an alkyl chain, that is, the C1 to C4 alkyl group represents that an alkyl chain is selected from the group consisting of methyl, ethyl, propyl, iso-propyl, n-butyl, iso-butyl, sec-butyl, and t-butyl.

Specifically for example, the alkyl group refers to a methyl group, an ethyl group, an isopropyl group, a butyl group, an isobutyl group, a t-butyl group, a pentyl group, a hexyl group, an ethenyl group, a propenyl group, a butenyl group, a cyclopropyl group, a cyclobutyl group, a cyclopentyl group, a cyclohexyl group, or the like.

Hereinafter, a chiral organic ligand according to an exemplary embodiment will be described, using Chemical Formulae 1, 2, and 3 to 10.

The present invention provides a chiral organic ligand which is any one selected from the group consisting of organic ligands represented by Chemical Formula 1 and Chemical Formula 2:

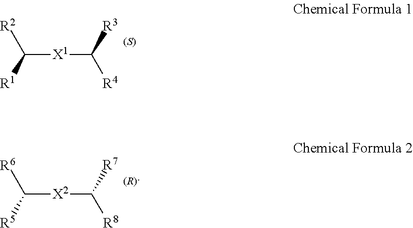

Chirality is a term indicating asymmetry, meaning that an object is not superposed onto the mirror image thereof. Chemical Formula 1 is a (S) type organic ligand, and Chemical Formula 2 is a (R) type organic ligand. A (S)/(R) nomenclature is a method of classifying enantiomers, and (S) and (R) types are determined, after substituents bonded to a chiral center are prioritized according to certain rules (e.g., Cahn-Ingold-Prelog priority rules). Specifically, when the chiral center is rotated, a substituent having a lowest priority is positioned farthest from a viewer to be hidden by the chiral center. Thereafter, when the priority of remaining three substituents is decreased in a clockwise direction, the compound is determined as a (R) type, and when decreased in a counterclockwise direction, the compound is determined as a (S) type.

Thick wedge and dotted wedge forms of side chains to which substituents of R¹ and R³ of Chemical Formula 1 and substituents of R⁵ and R⁷ of Chemical Formula 2 are connected represent (S) and (R) type organic ligands, respectively. As such, each of the chiral organic ligand according to an exemplary embodiment has (S) or (R) chiral side chains, as in Chemical Formulae 1 and 2, thereby having point chirality in which the enantiomers are not superimposed on each other, based on one point in the molecule.

Specifically, X¹ and X² in Chemical Formulae 1 and 2 are independently

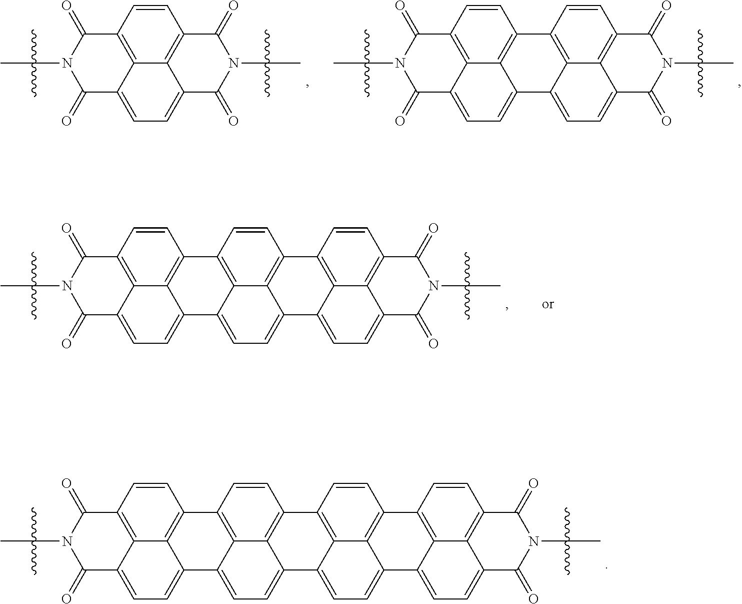

of each other

R¹ and R³ are independently of each other any one selected from the group consisting of a carboxy group, a hydroxyl group, an amino group, a sulfhydryl group, and a phosphate. R⁵ and R⁷ are independently of each other any one selected from the group consisting of a carboxy group, a hydroxyl group, an amino group, a sulfhydryl group, and a phosphate.

R² and R⁴ are independently of each other any one selected from the group consisting of C1 to C5 alkyl groups and C1 to C5 aryl groups. R⁶ and R⁸ are independently of each other any one selected from the group consisting of C1 to C5 alkyl groups and C1 to C5 aryl groups.

As an example, R¹, R³, R⁵, and R⁷ may be independently of one another any one selected from the group consisting of a carboxy group, a hydroxyl group, and an amino group, R², R⁴, R⁶, and R⁸ may be independently of one another any one selected from the group consisting of C1 to C3 alkyl groups and C1 to C3 aryl groups.

Particularly, R¹, R³, R⁵, and R⁷ may be a carboxy group, and R², R⁴, R⁶, and R⁸ may be a methyl group.

Taken together, a specific example of the chiral organic ligand according to an exemplary embodiment may include compounds represented by the following Chemical Formulae 3 to 10:

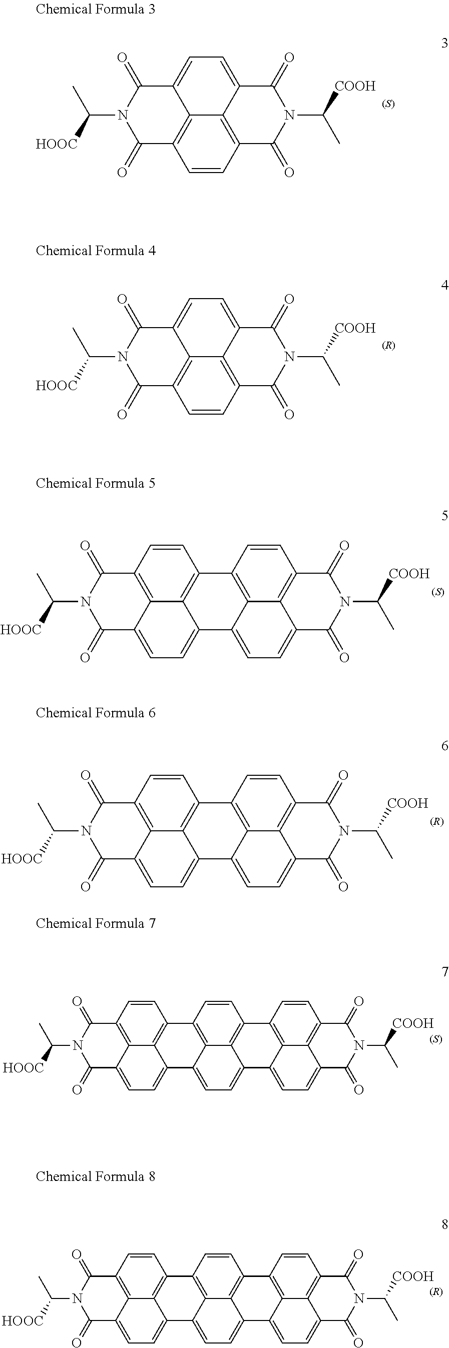

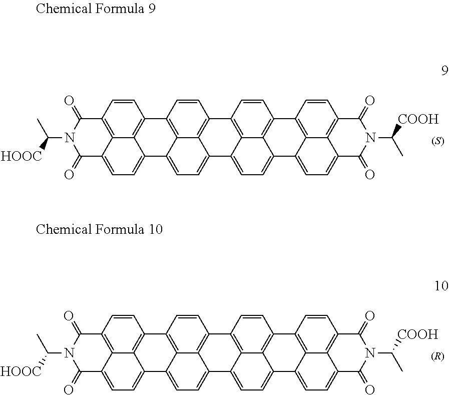 [SMILES: C[C@H](C(=O)O)N1C(=O)c2ccc3c4ccc5c6ccc7c8ccc9c%10c(ccc(c%11ccc(c%12ccc(c%13ccc(c2c3%13)C1=O)c4c5%12)c6c7%11)c%108)C(=O)N([C@H](C)C(=O)O)C9=O ; "(S)" ; C[C@@H](C(=O)O)N1C(=O)c2ccc3c4ccc5c6ccc7c8ccc9c%10c(ccc(c%11ccc(c%12ccc(c%13ccc(c2c3%13)C1=O)c4c5%12)c6c7%11)c%108)C(=O)N([C@@H](C)C(=O)O)C9=O ; "(R)"]

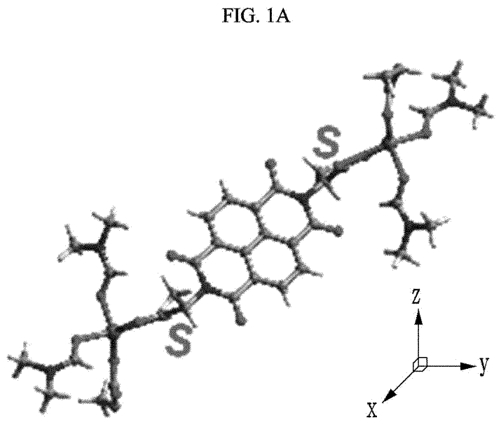

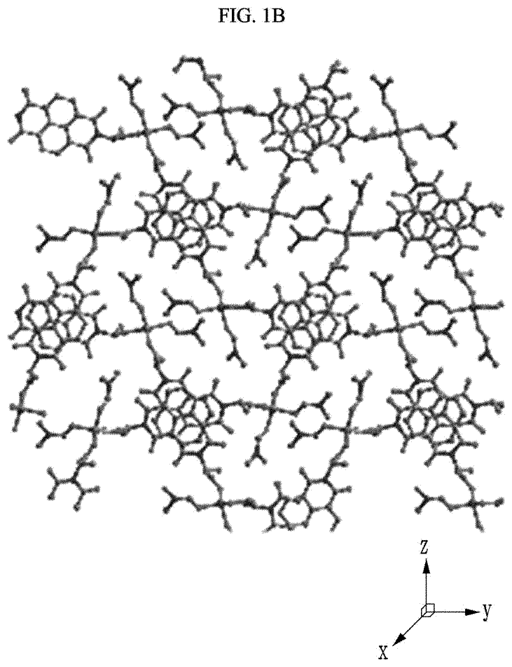

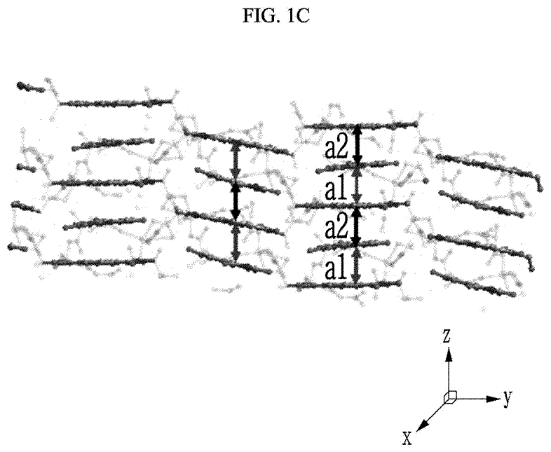

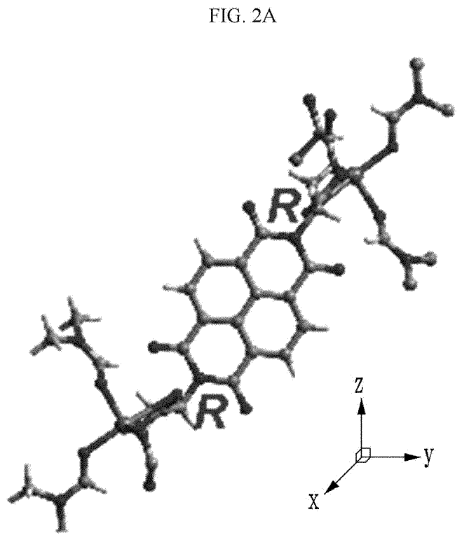

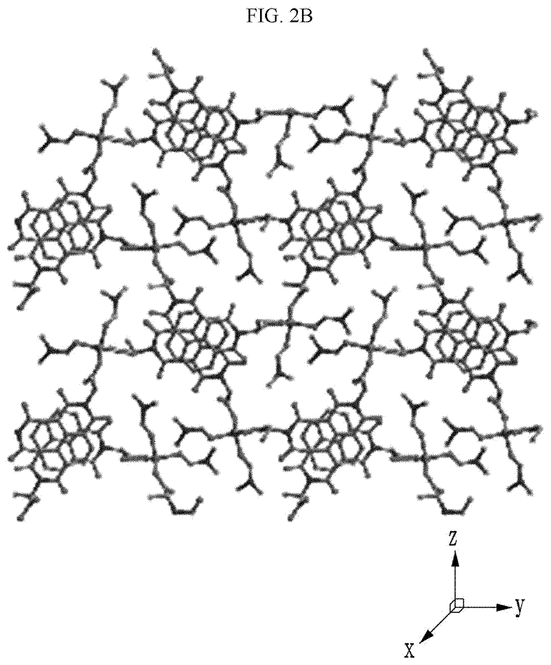

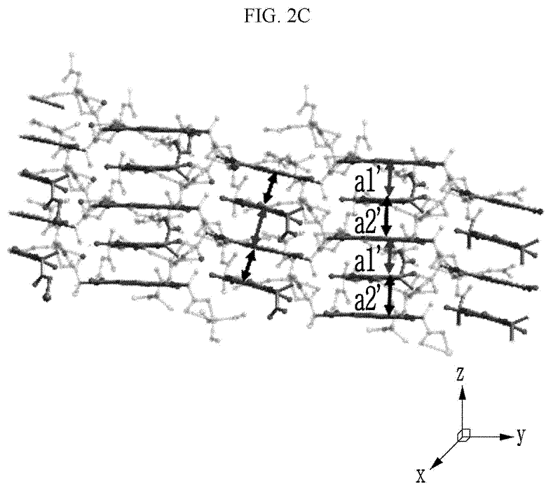

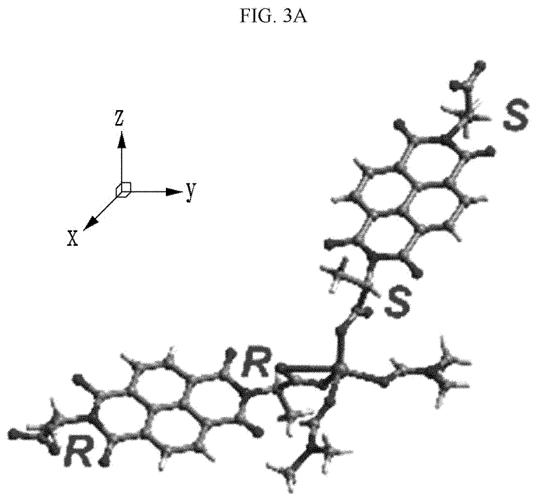

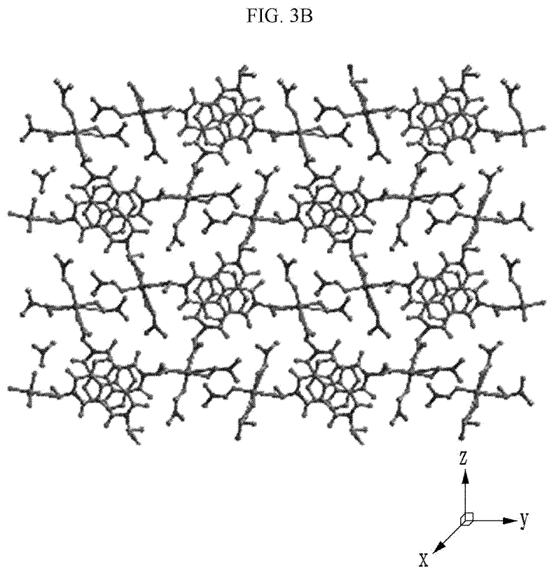

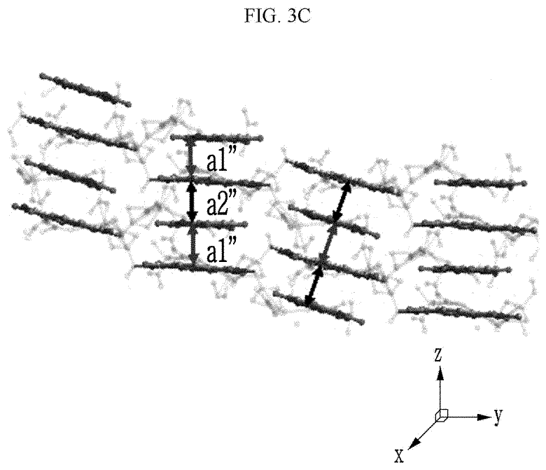

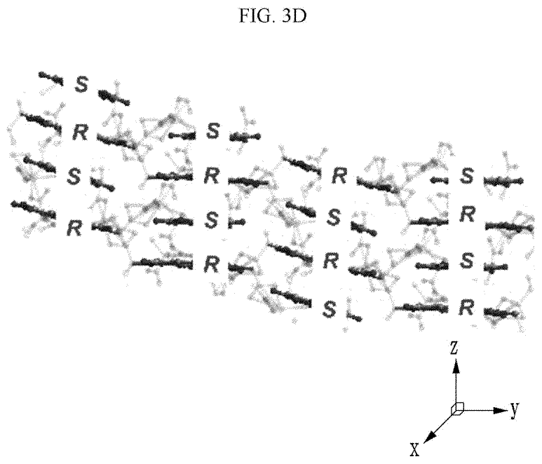

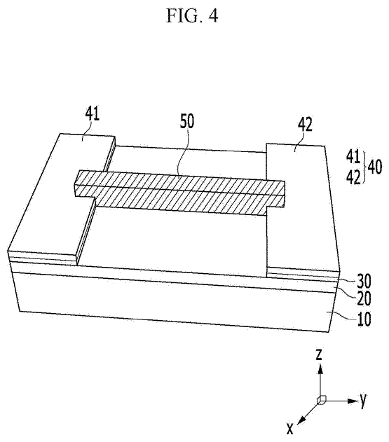

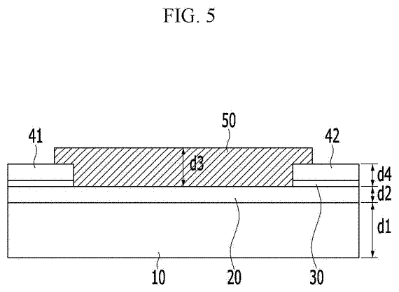

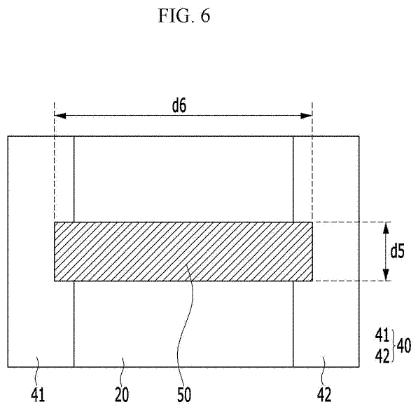

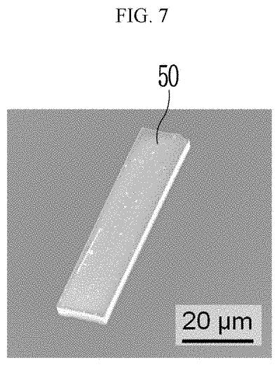

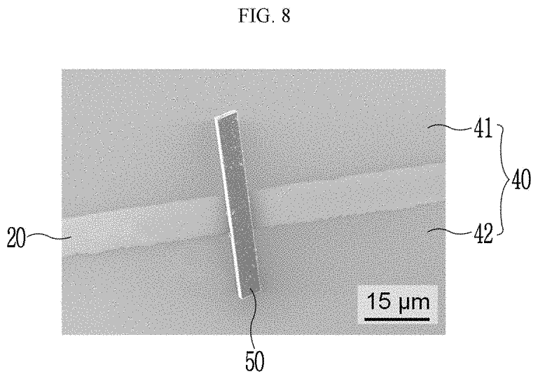

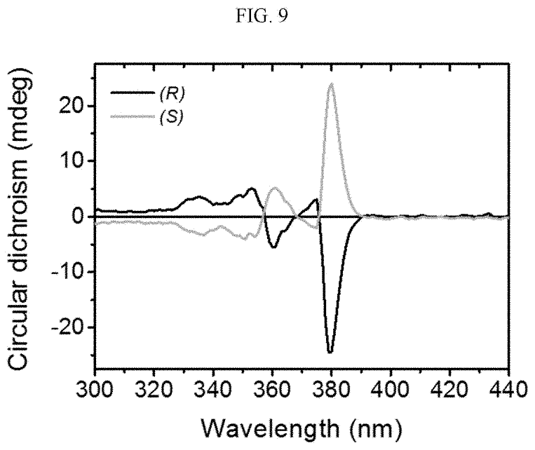

Hereinafter, the chiral complex supramolecular body according to an exemplary embodiment will be described, using FIGS. 1 to 3. FIGS. 1 to 3 are drawings illustrating a crystal structure of the chiral complex supramolecular body in which a (S), (R) or racemic type chiral organic ligand is coordinated with a metal ion, respectively. In FIGS. 1 to 3, rectangular coordinates including the x-axis, the y-axis, and the z-axis are illustrated, which represent that each crystal structure has three-dimensional structure.

First, referring to FIGS. 1A to 10, the chiral complex supramolecular body in which a (S) type chiral organic ligand is coordinated with a metal ion will be described. FIG. 1A is a drawing illustrating a unit crystal structure of a chiral complex supramolecular body in which a (S) type chiral organic ligand is coordinated with a metal ion, FIG. 1B is a drawing illustrating a crystal structure of a chiral complex supramolecular body in which a (S) type chiral organic ligand is coordinated with a metal ion viewed from the xy plane, and FIG. 10 is a drawing illustrating a crystal structure of FIG. 1B viewed from the xy plane.

When X¹ of Chemical Formula 1 is

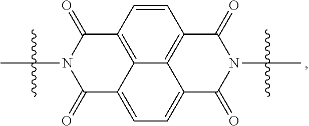 [SMILES: *N1C(=O)c2ccc3c4c(ccc(c24)C1=O)C(=O)N(*)C3=O]

the chiral complex supramolecular body according to an exemplary embodiment of FIG. 1 includes a chiral organic ligand in which substituents are bonded to both sides of nitrogen (N) atoms of X¹ to become the (S) type. The chiral organic ligand and a metal ion are coordinated with each other to form a complex. As shown in FIG. 1B, the chiral complex of FIG. 1A is formed in the entire system to produce the chiral complex supramolecular body according to an exemplary embodiment.

Here, referring to FIG. 10, a distance between adjacent chiral complexes has a constant regularity. FIG. 10 is a side view of a crystal structure of FIG. 1B viewed from the side, and a distance between adjacent chiral complexes is referred to as a first distance a1 and a second distance a2, alternately. The chiral complex supramolecular body according to FIG. 1B is formed to alternately have the first distance a1 and the second distance a2 between adjacent unit molecules. The first distance a1 may be about 3.70 Å and the second distance a2 may be about 3.59 Å.

Referring to FIGS. 2A to 2C, a chiral complex supramolecular body in which a (R) type chiral organic ligand is coordinated with a metal ion will be described. FIG. 2A is a drawing illustrating a unit crystal structure of a chiral complex supramolecular body in which a (R) type chiral organic ligand is coordinated with a metal ion, FIG. 2B is a drawing illustrating a crystal structure of a chiral complex supramolecular body in which a (R) type chiral organic ligand is coordinated with a metal ion viewed from the xy plane, and FIG. 2C is a drawing illustrating a crystal structure of FIG. 2B viewed from the xz plane.

When X¹ is

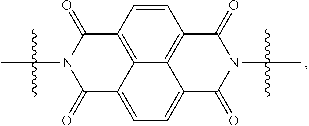 [SMILES: *N1C(=O)c2ccc3c4c(ccc(c24)C1=O)C(=O)N(*)C3=O]

the chiral complex supramolecular body according to an exemplary embodiment of FIG. 2 includes a chiral organic ligand in which substituents are bonded to both sides of nitrogen (N) atoms of X¹ to become the (R) type. The chiral organic ligand and a metal ion are coordinated with each other to form a complex. As shown in FIG. 2B, the chiral complex of FIG. 2A is formed in the entire system to produce the chiral complex supramolecular body according to an exemplary embodiment.

Here, referring to FIG. 2C, a distance between adjacent chiral complexes has a constant regularity. FIG. 2C is a side view of a crystal structure of FIG. 2B viewed from the side, and a distance between adjacent chiral complexes is referred to as a first distance a1′ and a second distance a2′, alternately. The chiral complex supramolecular body according to FIG. 2B is formed to alternately have the first distance a1′ and the second distance a2′ between adjacent unit molecules. The first distance a1′ may be about 3.72 Å and the second distance a2′ may be about 3.52 Å.

Referring to FIGS. 3A to 3D, a chiral complex supramolecular body in which a racemic chiral organic ligand is coordinated with a metal ion will be described. FIG. 3A is a drawing illustrating a unit crystal structure of a chiral complex supramolecular body in which a racemic type chiral organic ligand is coordinated with a metal ion, FIG. 3B is a drawing illustrating a crystal structure of a chiral complex supramolecular body in which a racemic type chiral organic ligand is coordinated with a metal ion viewed from the xy plane, FIG. 3C is a drawing illustrating a crystal structure of FIG. 3B viewed from the xz plane, and FIG. 3D is a drawing illustrating a crystal structure of FIG. 3C to be easily understood.

When X¹ of Chemical Formula 1 is

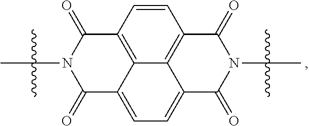 [SMILES: *N1C(=O)c2ccc3c4c(ccc(c24)C1=O)C(=O)N(*)C3=O]

the chiral complex supramolecular body according to an exemplary embodiment of FIG. 3 includes a chiral organic ligand in which substituents are bonded to both sides of nitrogen (N) atoms of X¹ to become a racemic type. The chiral organic ligand and a metal ion are coordinated with each other to form a complex. As shown in FIG. 3B, the chiral complex of FIG. 3A is formed in the entire system to produce the chiral complex supramolecular body according to an exemplary embodiment.

In the supramolecular body of FIG. 2B using a racemic type ligand, the (S) type chiral organic ligand and the (R) type chiral organic ligand are alternately arranged, as shown in FIG. 3D. As such the (S) type and the (R) type are alternately bonded, whereby the racemic type chiral supramolecular body shows a chiral discrimination phenomenon. It may be confirmed from the chiral discrimination phenomenon that the chiral complex supramolecular body according to an exemplary embodiment is self-assembled.

Here, referring to FIG. 3C, a distance between adjacent chiral complexes has a constant regularity. FIG. 3C is a side view of a crystal structure of FIG. 3B viewed from the side, and a distance between adjacent chiral complexes is referred to as a first distance a1″ and a second distance a2″, alternately. The chiral complex supramolecular body according to FIG. 3B is formed to alternately have the first distance a1″ and the second distance a2″ between adjacent unit molecules. The first distance a1″ may be about 3.63 Å and the second distance a2″ may be about 3.61 Å.

The chiral complex supramolecular body according to an exemplary embodiment is formed by coordinating a chiral organic ligand which is any one selected from the group consisting of organic ligands represented by Chemical Formula 1 and Chemical Formula 2 with a metal ion. Here, the metal ion may be any one selected from the group consisting of zinc (Zn), copper (Cu), nickel (Ni), cadmium (Cd), iron (Fe), chromium (Cr), cobalt (Co), calcium (Ca), magnesium (Mg), manganese (Mn), silver (Ag), and gold (Au). In addition, the chiral complex supramolecular body may have a ribbon shape.

Hereinafter, the present invention will be described in more detail, through Examples. However, the Examples are only for illustration, and the scope of the present invention is not limited thereto.

A preparation method of the chiral organic ligand according to an exemplary embodiment will be described (Example 1).

First, a preparation method of a (S) type chiral organic ligand will be described (Example 1-1).

0.005 mol of (S)-1,4,5,8-naphthalenetetracarboxylic dianhydride and 0.01 mol of alanine are sufficiently dissolved in 600 mL of pyridine, and reacted while refluxing the reactants at 115° C. for 12 hours.

When the volume of the solution is down to about 10 mL during the reflux process, hydrogen chloride (100 mL HCl in 300 mL water) is added, separated by a filter, and washed using water, thereby preparing a naphthalene diimide (NDI) ligand of the following Chemical Formula 11 having chirality:

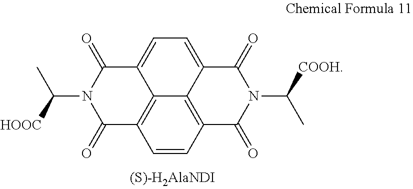 [SMILES: C[C@H](C(=O)O)N1C(=O)c2ccc3c4c(ccc(c24)C1=O)C(=O)N([C@H](C)C(=O)O)C3=O]

The NMR data of the (S) type chiral organic ligand prepared according to Example 1-1 is as follows.

1H NMR (Me₂SO-d₆, 500 MHz): δ 8.69 (s, 4H, naphthalene ring) 5.59 (q, 2H, J 6.5 Hz) 1.57 (d, 3H, J7 Hz). 13C NMR (Me₂SO-d₆, 500 MHz): d 171.2 (two equivalent carbonyls of carboxylic acid) 162.1 (four equivalent carbonyls), 131.1, 126.2 (aromatic carbons), 49.2 (chiral carbon), 14.5 (methylene carbon).

Next, a preparation method of the (R) type chiral organic ligand will be described (Example 1-2).

The naphthalene diimide (NDI) ligand of the following Chemical Formula 12 is prepared in the same manner as in Example 1-1, except that (R)-1,4,5,8-naphthalenetetracarboxylic dianhydride is used instead of (S)-1,4,5,8-naphthalenetetracarboxylic dianhydride:

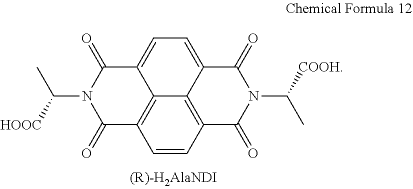 [SMILES: C[C@@H](C(=O)O)N1C(=O)c2ccc3c4c(ccc(c24)C1=O)C(=O)N([C@@H](C)C(=O)O)C3=O]

The NMR data of the (R) type chiral organic ligand prepared according to Example 1-2 is as follows.

1H NMR (Me₂SO-d₆, 500 MHz): δ 8.69 (s, 4H, naphthalene ring) 5.59 (q, 2H, J 6.5 Hz) 1.57 (d, 3H, J7 Hz). 13C NMR (Me₂SO-d₆, 500 MHz): d 171.2 (two equivalent carbonyls of carboxylic acid) 162.1 (four equivalent carbonyls), 131.1, 126.2 (aromatic carbons), 49.2 (chiral carbon), 14.5 (methylene carbon).

Hereinafter, the preparation method of a chiral complex supramolecular body according to an exemplary embodiment will be described (Example 2).

First, a preparation method of a (S) type chiral complex supramolecular body will be described (Example 2-1).

0.1 mmol of the (S) type chiral organic ligand prepared according to Example 1-1 and 0.1 mmol of zinc iodide (ZnI₂) powder are dissolved in 3 mL of N,N-dimethylmethanamide (DMF) to prepare a solution which is placed in a Teflon tube, and then placed again in a stainless-steel tube which is then sealed. The stainless-steel tube is heated in an oven at 120° C. for 72 hours to proceed with the reaction to produce a crystal, which is filtered and washed with N,N-dimethylmethanamide (DMF) several times, thereby preparing a (S) type chiral complex supramolecular body having a ribbon shape. The (S) type chiral complex supramolecular body is dissolved in ethanol for manufacturing a device. (yield=29%)

The elemental analysis data of the (S) type chiral complex supramolecular body prepared according to Example 2-1 is as follows.

Anal. Calcd. for C₂₆H₂₆ZnN₄O₁₀ (%): C, 50.38, H, 4.23, N, 9.04; found (%): C, 50.13, H, 4.10, N, 8.70.

Next, a preparation method of a (R) type chiral complex supramolecular body will be described (Example 2-2).

A (R) type chiral complex supramolecular body having a ribbon shape is prepared in the same manner as in Example 2-1, except that 0.1 mmol of the (R) type chiral organic ligand prepared according to Example 1-2 is used instead of 0.1 mmol of the (S) type chiral organic ligand prepared according to Example 1-1. (yield=27%)

The elemental analysis data of the (R) type chiral complex supramolecular body prepared according to Example 2-2 is as follows.

Anal. Calcd. for C₂₆H₂₆ZnN₄O₁₀ (%): C, 50.38, H, 4.23, N, 9.04; found (%): C, 50.07, H, 4.11, N, 8.72.

Next, a preparation method of a racemic chiral complex supramolecular body will be described (Example 2-3).

A racemic type chiral complex supramolecular body having a ribbon shape is prepared in the same manner as in Example 2-1, except that 0.05 mmol of the (S) type chiral organic ligand prepared according to Example 1-1 and 0.05 mmol of the (R) type chiral organic ligand prepared according to Example 1-2 are used instead of 0.1 mmol of the (S) type chiral organic ligand prepared according to Example 1-1. (yield=21%)

The elemental analysis data of the racemic type chiral complex supramolecular body prepared according to Example 2-3 is as follows.

Anal. Calcd. for C₂₆H₂₆ZnN₄O₁₀ (%): C, 50.38, H, 4.23, N, 9.04; found (%): C, 50.05, H, 4.22, N, 8.93.

Hereinafter, a manufacturing method of an organic electronic device having the chiral complex supramolecular body according to an exemplary embodiment as an active layer according will be described (Example 3).

First, a manufacturing method of an organic electronic device including a (S) type chiral complex supramolecular body active layer will be described (Example 3-1).

A n-type doped silicon wafer is prepared as a substrate. The silicon wafer has a 300 nm silicon oxide thin film formed thereon, and this is used as a gate dielectric material of a transistor (capacitance=11.5 nF/cm²). The surface of the silicon oxide thin film is treated with a piranha solution (a mixed solution of 70 vol % H₂SO₄ and 30 vol % H₂O₂), and n-octadecyltrimethoxysilane (OTS) is spin coated to form a self-assembled monolayer (SAM). The wafer was placed in a desiccator saturated with ammonia water for a day to remove residual n-octadecyltrimethoxysilane (OTS), and washed using toluene, acetone, or isopropyl alcohol.

An ethanol solution in which the (S) type chiral complex supramolecular body of Example 2-1 is dispersed is coated on a substrate, and dried in a vacuum oven at 60° C. for a day to remove residual ethanol, thereby preparing an active layer. Next, a gold electrode is patterned on the active layer using heat deposition and a shadow mask, thereby manufacturing an organic sensor device.

Next, a manufacturing method of an organic electronic device including the (R) type chiral complex supramolecular body active layer will be described (Example 3-2).

An organic sensor device is manufactured in the same manner as in Example 3-1, except that an ethanol solution in which the (R) type chiral complex supramolecular body of Example 2-2 is dispersed is used, instead of the ethanol solution in which the (S) type chiral complex supramolecular body of Example 2-1 is dispersed.

Next, a manufacturing method of an organic electronic device including the racemic type chiral complex supramolecular body active layer will be described (Example 3-3).

An organic sensor device is manufactured in the same manner as in Example 3-1, except that an ethanol solution in which the racemic type chiral complex supramolecular body of Example 2-3 is dispersed is used, instead of the ethanol solution in which the (S) type chiral complex supramolecular body of Example 2-1 is dispersed.

The chiral complex supramolecular body according to the above-described exemplary embodiment may be used in an active layer of an organic electronic device, which will be described below.

Hereinafter, an organic electronic device according to an exemplary embodiment will be described, using FIGS. 4 to 6. FIG. 4 is a perspective view illustrating a three-dimensional schematic structure of the organic electronic device according to an exemplary embodiment, FIG. 5 is a front view illustrating a schematic structure of the organic electronic device according to an exemplary embodiment viewed from the yz plane, and FIG. 6 is a top view illustrating a schematic structure of the organic electronic device according to an exemplary embodiment viewed from the xy plane.

Referring to FIGS. 4 to 6, the organic electronic device according to an exemplary embodiment may include a substrate 10, a gate insulation film 20, a surface modified layer 30, an electrode 40, and an active layer 50.

An substrate 10 may include materials such as glass, metal or plastic, and has a thickness d1 of about 250 μm to about 300 μm. However, the material and thickness of the substrate 10 are not limited thereto.

On the substrate 10, a gate insulation film 20 is disposed. The gate insulation film 20 may include materials such as silicon nitride (SiNₓ), silicon oxide (SiOₓ), and aluminum oxide (AlₓO_{y}). The gate insulation film 20 may have a thickness d2 of about 250 nm to about 350 nm. Between the substrate 10 and the gate insulation film 20, a gate electrode (not shown) is disposed, and the gate insulation film 20 may serve as the gate dielectric material.

On the gate insulation film 20, a surface modified layer 30 may be disposed. The surface modified layer 30 may include a self-assembled monolayer (SAM) formed by surface-treating the substrate 10 with any one selected from the group consisting of n-octadecyltrimethoxysilane (OTS), n-octadecyltrichlorosilane, n-octyltrichlorosilane, n-octylphosphate, and n-octadecylphosphate. Particularly, the surface modified layer 30 may be a self-assembled monolayer (SAM) in which the substrate 10 is surface-treated with n-octadecyltrimethoxysilane (OTS).

On the surface modified layer 30, an electrode 40 including gold (Au) or chromium (Cr) is disposed. The electrode 40 includes a first electrode 41 and a second electrode 42, and one of the first electrode 41 and the second electrode 42 may be a source electrode and the other one may be a drain electrode, depending on the direction in which voltage or current is applied.

Here, the first electrode 41 and the second electrode 42 may be formed, so that a portion of the gate insulation film 20 is exposed by an etching process using a pattern mask, after the surface modified layer 30 and a material layer forming the electrode 40 are sequentially laminated on the gate insulation film 20. A portion of the exposed gate insulation film 20 may be brought into contact with the active layer 50. According to an exemplary embodiment, the surface modified layer 30, the first electrode 41, and the second electrode 42 may be formed without an etching process.

The surface modified layer 30 may have a thickness (not shown) of about 5 nm or less, and the electrode 40 may have a thickness (not shown) of about 40 nm. Therefore, the total thickness d4 of the surface modified layer 30 and the electrode 40 may be about 45 nm or less.

On the gate insulation film 20, the surface modified layer 30, and the electrode 40, an active layer 50 may be disposed. The active layer 50 includes a chiral complex supramolecular body formed by coordinating a chiral organic ligand which is any one selected from the group consisting of organic ligands represented by Chemical Formula 1 and Chemical Formula 2 with a metal ion which is any one selected from the group consisting of zinc (Zn), copper (Cu), nickel (Ni), cadmium (Cd), iron (Fe), chromium (Cr), cobalt (Co), calcium (Ca), magnesium (Mg), manganese (Mn), silver (Ag), and gold (Au).

The active layer 50 includes the chiral complex supramolecular body according to an exemplary embodiment, thereby securing supramolecular chirality in which the entire active layer 50 has chirality. The chirality refers to asymmetry in which a chemical structure is not superposed onto the mirror image thereof, as described above, and most of amino acids, sugars, enzymes, and the like which exist in nature have chirality. Medicines may be also prepared as an enantiomer having chirality. Here, since one of the compounds in an enantiomer relationship may be used as a medicine, and the other one may have a potential side effect, there is a need for a technique to separate and detect the two compounds.

Meanwhile, circular polarization is light having chirality in a polarization state, and has a polarization form different from linear polarization. A technique to separate and detect materials having a circular polarization characteristic and a linear polarization characteristic is likely to be utilized in optical communication technology and polarization imaging. Particularly, in the case of the optical communication technology, the circular polarization may transfer new information of a polarization form, in addition to a wavelength band or intensity which is basic information of electromagnetic waves. Therefore, possibility to be applied to optical communication technology which is encrypted or has enhanced security may be high.

Since complex optical equipment such as a linear polarizing plate and a phase retardation plate is required for detecting circular polarization having left and right directionalities, there is a problem in that downsizing or integration of sensing equipment is difficult. In order to solve the problem, a study on an electronic device detecting circular polarization light was conducted, however, the wavelength band of detected light is limited to wavelengths in an ultraviolet region of about 360 nm and an infrared region of about 1200 nm or more, and there is a problem in that a photosensitive characteristic and electrical properties are poor.

Accordingly, circular polarization in a visible light region having high usage in real life is not selectively detected, and light sensing capability is very poor, and consequently, there is a problem in that application and use as an actual electronic device are difficult.

Thus, the organic electronic device according to an exemplary embodiment includes an active layer 50 including a chiral complex supramolecular body. The entire of an organic electronic device system may secure chirality by a supramolecular body in which a chiral organic ligand and a metal ion are coordinated with each other. Misarranged orientation which is disadvantageous in charge transfer is minimized, thereby providing an organic electronic device having greatly improved photosensitivity and electrical characteristics. In addition, since a manufacturing method of the organic electronic device according to an exemplary embodiment is very simple, and easily applicable even on a plastic substrate 10, the organic electronic device is advantageous for integrated devices and downsizing. The manufacturing method of the organic electronic device according to an exemplary embodiment will be described later.

Particularly, the organic electronic device according to an exemplary embodiment may be utilized as various chirality sensors which detect various elements having chirality such as light and chemical gas with high performance.

The active layer 50 may have a thickness d3 of about 200 nm to about 1000 nm, referring to FIG. 5. The active layer 50 may have a vertical width d5 of about 1 μm to about 5 μm, and a horizontal length d6 of about 10 μm or less, referring to FIG. 6.

According to an exemplary embodiment, the electrode 40 may be disposed on the active layer 50. However, when the electronic device is manufactured so that the active layer 50 is disposed on the electrode 40 as in the above Example, simplification of the manufacturing process such as reducing manufacturing time may be promoted, and relatively high safety may be secured.

Hereinafter, the manufacturing method of the organic electronic device including the chiral complex supramolecular body according to FIGS. 4 to 6 will be described.

First, (a) substrate 10 is provided.

After step (a), (a′) one surface of the substrate 10 is oxidation-treated to manufacture a substrate 10 including a hydroxyl group (—OH) on the one surface. The surface including a hydroxyl group (—OH) may be a gate insulation film 20.

After step (a′), (a″) a self-assembled monolayer (SAM) may be formed on the surface of the substrate 10 which is oxidation-treated. The self-assembled monolayer (SAM) may be formed by treating the oxidation-treated surface of the substrate 10 with any one selected from the group consisting of n-octadecyltrimethoxysilane (OTS), n-octadecyltrichlorosilane, n-octyltrichlorosilane, n-octylphosphate, and n-octadecylphosphate, particularly, n-octadecyltrimethoxysilane (OTS).

The self-assembled monolayer (SAM) may be a surface modified layer 30.

Next, (b) an electrode 40 including gold or chromium is formed on the substrate 10. The electrode 40 may form a first electrode 41 and a second electrode 42 together with the surface modified layer 30 formed in step (a″).

Next, (c) an active layer 50 is formed on the first electrode 41 and second electrode 42 to manufacture the organic electronic device.

The active layer 50 includes a chiral complex supramolecular body formed by coordinating a chiral organic ligand which is any one selected from the group consisting of organic ligands represented by Chemical Formula 1 and Chemical Formula 2 with a metal ion which is any one selected from the group consisting of zinc, copper, nickel, cadmium, iron, chromium, cobalt, calcium, magnesium, manganese, silver, and gold.

Step (c) may include (c-1) manufacturing a chiral complex supramolecular body having a ribbon shape by coordinating the chiral organic ligand with the metal, and (c-2) forming the active layer 50 including the chiral complex supramolecular body on the substrate 10.

According to an exemplary embodiment, the active layer 50 may be first formed on the substrate 10, and the electrode 40 including the first electrode 41 and the second electrode 42 may be formed thereon.

Hereinafter, specific shapes of the chiral complex supramolecular body and the organic electronic device according to an exemplary embodiment will be described, using FIGS. 7 and 8. FIG. 7 is a scanning electron microscopic (SEM) image of a single crystal of the chiral complex supramolecular body according to an exemplary embodiment, and FIG. 8 is a scanning electron microscopic (SEM) image of a portion of the organic electronic device according to an exemplary embodiment.

Referring to FIG. 7, a single crystal of the chiral complex supramolecular body according to an exemplary embodiment may have a thin rectangular form. It may be a ribbon shape having a one-dimensional planar characteristic, in which the length of the rectangle is about 10 times or less the horizontal length of the rectangle. As such, it is confirmed that the single crystal of the chiral complex supramolecular body according to an exemplary embodiment has a ribbon-shaped morphology having a tens of micrometer (μm) size.

Referring to FIG. 8, it is confirmed that in the organic electronic device (particularly, organic sensor) according to an exemplary embodiment, the active layer 50 including the chiral complex supramolecular body according to an exemplary embodiment is arranged on the electrode 40. The electrode 40 includes the first electrode 41 and the second electrode 42, and may include gold (Au) or chromium (Cr). The electrode 40 may be patterned on the substrate 10 (see FIG. 4) or the gate insulation film 20 (see FIG. 4).

The chiral complex supramolecular body formed on the electrode 40 becomes the active layer 50 of the organic electronic device, and may serve to detect various elements having chirality. The active layer 50 may be disposed to cross the first electrode 41 and the second electrode 42 with the gate insulation film 20 including silicon oxide and the like interposed therebetween.

The organic electronic device according to an exemplary embodiment may be one or more selected from the group consisting of organic transistors, organic light emitting diodes, and organic solar cells, as well as organic sensors, as described above.

When the organic electronic device is the organic sensor, the organic sensor may detect one or more selected from the group consisting of light, chemical gas, alcohol, hydrazine (N₂H₄), and medicines. The chemical gas may include an amine solution including a nitrogen element such as aniline, trimethylamine (TEA), and phenylethylamine (PEA), a polar solvent, and the like.

Hereinafter, the characteristics of the chiral complex supramolecular body according to an exemplary embodiment will be described, using FIGS. 9 and 10. FIGS. 9 and 10 are graphs illustrating spectrum analysis results using circular dichroism (CD) of the chiral organic ligand and the chiral complex supramolecular body according to an exemplary embodiment. The circular dichroism (CD) is one of the characterization methods used when confirming chirality.

Referring to FIG. 9, it is confirmed that the circular dichroism (CD) spectra of the (S) type and (R) type chiral organic ligands (Examples 1-1 and 1-2) have positive and negative peaks at about 380 nm, respectively.

Referring to FIG. 10, the circular dichroism (CD) spectrum of the racemic type chiral complex supramolecular body (Example 2-3, Rac) is formed almost linearly, so as not to have a distinguishable form. However, it is confirmed that the (S) type and (R) type chiral complex supramolecular bodies represent a mirror image spectrum having peaks in opposite positive and negative directions, respectively.

The chiral complex supramolecular body (Examples 2-1 to 2-3) of FIG. 10 represents a spectrum which is shifted farther to the right, that is, to a long wavelength (red-shifted), as compared with the chiral organic ligand of FIG. 9 (Examples 1-1 and 1-2). This shows that the chiral complex supramolecular body has much improved chirality as compared with the chiral organic ligand. That is to say, the chirality of the chiral organic ligand (Examples 1-1 and 1-2) derives chirality in the entire organic electronic device and is amplified to represent a supramolecular chirality phenomenon, in the course of synthesizing the chiral complex supramolecular body (Examples 2-1 to 2-3).

Hereinafter, referring to FIGS. 11 to 13, response of the chiral complex supramolecular body according to an exemplary embodiment to light will be described. FIG. 11 is a graph illustrating absorbance of the organic electronic device including the chiral complex supramolecular body according to Example 3-3, FIG. 12 is a graph illustrating a current-voltage curve (I-V curve) of the chiral complex supramolecular body according to an exemplary embodiment, and FIG. 13 is a graph illustrating powder X-ray diffraction (PXRD) analysis results before and after irradiation of ultraviolet (UV) light on the chiral complex supramolecular body according to an exemplary embodiment.

Referring to FIG. 11, it is confirmed that when the chiral complex supramolecular body according to Example 2-3 is irradiated with ultraviolet light (UV light) at 365 nm for 1 hour, absorbance is greatly decreased at a wavelength of 450 nm or more, resulted in greatly increased ultraviolet intensity. At the same time, it is confirmed that due to the formation of radical negative ions, the color of the supramolecular body crystal according to Example 2-3 is changed to black.

Referring to FIG. 12, it is confirmed that when the organic electronic device according to Example 3-3 is irradiated with ultraviolet light at 365 nm, conductivity is greatly increased. That is, it is confirmed that photosensitivity to ultraviolet rays is improved by the change of current.

Referring to FIG. 13, it is represented that the crystal of the chiral complex supramolecular body according to Example 2-3 has the same crystal structure as the crystal structure before irradiation, even after irradiated with ultraviolet light. This shows that response to ultraviolet light does not occur due to collapse of the crystal structure.

Hereinafter, referring to FIGS. 14 to 16, the sensing characteristic for the amine compound of the chiral complex supramolecular body according to an exemplary embodiment will be described using photoluminescence characteristics. As an example of the amine compound, description will be provided for hydrazine.

FIG. 14 is a graph illustrating luminescence intensity of a chiral complex supramolecular body according to an exemplary embodiment, depending on a wavelength for a concentration of hydrazine, and FIGS. 15 and 16 are graphs illustrating luminescence intensity of a chiral complex supramolecular body according to an exemplary embodiment, depending on a concentration of hydrazine, respectively.

Spectrometry using luminescence characteristics may be used for analyzing the atomic or molecular structure of a certain material. Spectrometry uses the characteristics in which when a certain material absorbs light, electron potential in the material is changed, whereby absorbance and light intensity are changed. Luminescence may be classified into fluorescence, phosphorescence, chemiluminescence, thermoluminescence, or the like, depending on the aspect. Among them, fluorescence and phosphorescence emit light in a manner that light is absorbed to transit electrons from a ground state to an unstable excited state, and when the electrons return to the ground state, heat or light at another wavelength is emitted. The fluorescence and phosphorescence is referred to as photoluminescence (PL).

The fluorescence more easily occurs than phosphorescence, and stays in the excited state for a short time so that interference between signals is small, and thus, may be advantageous for being used as an analysis method. Thus, an exemplary embodiment will be described through an experiment results measuring fluorescence intensity during photoluminescence (PL).

The fluorescence characteristics of a certain material may be affected by a molecular structure and chemical environment. As an example, the fluorescence intensity of a certain material may be affected by a quenching phenomenon. The quenching phenomenon refers to a phenomenon in which fluorescence intensity is decreased by another certain compound present in a certain material.

Hereinafter, the sensing characteristic of the chiral complex supramolecular body according to an exemplary embodiment for the amine compound, in particular, hydrazine (N₂H₄) will be described by the photoluminescence (PL) quenching phenomenon.

Referring to FIG. 14, the fluorescence intensity of the chiral complex supramolecular body of Example 2-3 for the concentration of hydrazine. As the concentration of hydrazine is increased, that is, lowered along the direction of an arrow shown in FIG. 14, the fluorescence intensity is decreased by the photoluminescence (PL) quenching phenomenon. This represents that the complex supramolecular body according to an exemplary embodiment senses hydrazine well for each concentration.

Referring to FIG. 15, the fluorescence intensity depending on the concentration of hydrazine of Example 2-3 is illustrated. It is confirmed that as the concentration of hydrazine shown on the horizontal axis is increased in a log scale, the fluorescence intensity of Example 2-3 shown on the vertical axis is decreased.

Referring to FIG. 16, on the horizontal axis, the concentration of hydrazine is shown in a linear scale, and the vertical axis represents a quenching degree with a change in fluorescence intensity (A intensity). According to FIG. 16, it is confirmed that when the concentration of hydrazine is linearly increased, the quenching degree is also linearly increased.

As such, it is confirmed that the chiral complex supramolecular body according to an exemplary embodiment has a quenching degree in proportion to the concentration of hydrazine, effectively senses the concentration of hydrazine, and allows hydrazine to be selectively distinguished by the photoluminescence (PL) quenching phenomenon.

Hereinafter, referring to FIG. 17, the sensing characteristics for another amine compound of the chiral complex supramolecular body according to an exemplary embodiment will be described using photoluminescence characteristics. In the present Example, description will be provided for trimethylamine, phenylethylamine, and hydrazine described above, as an example of the amine compound.

FIG. 17 is a graph illustrating a sensing degree for the amine compound (amine solution) of the chiral complex supramolecular body according to an exemplary embodiment. Trimethylamine (TEA) is represented by a chemical formula of C₃H₉N, and phenylethylamine (PEA) is represented by a chemical formula of C₈H₁₁N.

Referring to FIG. 17, luminescence intensity depending on wavelengths for the Comparative Example of the chiral complex supramolecular body according to an exemplary embodiment, trimethylamine (TEA), phenylethylamine (PEA), and hydrazine is illustrated. Here, hydrazine, trimethylamine (TEA), and phenylethylamine (PEA) have a concentration of 1 M, respectively. The Comparative Example represents a material to which hydrazine, trimethylamine (TEA), and phenylethylamine (PEA) are not added.

As compared with the Comparative Example, the luminescence intensity for the material to which an amine compound is added is rapidly decreased by the above-described quenching phenomenon. Specifically, a quenching degree is increased in the order of hydrazine, trimethylamine (TEA), and phenylethylamine (PEA). Particularly, in the case of hydrazine, luminescence intensity is close to 0, and thus, it is found that the chiral complex supramolecular body according to an exemplary embodiment most sensitively senses hydrazine among the amine compounds. The material to which trimethylamine (TEA) or phenylethylamine (PEA) is added is quenched to a similar degree, and trimethylamine (TEA) is a little more quenched than phenylethylamine (PEA).

As such, when various amine compounds are added at a constant concentration (1M in the present Example), the chiral complex supramolecular body according to an exemplary embodiment has sensing ability which is excellent in the order of hydrazine, trimethylamine (TEA), and phenylethylamine (PEA).

In addition, the wavelength region to be quenched may be in a range of about 420 nm to about 600 nm, that is, a visible light region, and in particular in a range of about 450 nm to about 550 nm.

As seen from FIGS. 14 to 17, the chiral complex supramolecular body according to an exemplary embodiment may effectively sense various amine compounds including nitrogen by photoluminescence (PL) analysis.

Hereinafter, the sensing characteristics for a medicine of the organic electronic device according to an exemplary embodiment will be described by photoluminescence (PL) characteristics, using FIGS. 18 to 20. The organic electronic device of the present Example includes the (S) type chiral complex supramolecular body (Example 2-1), and the description will be provided for naproxen as an example of the medicine.

FIG. 18 is a graph illustrating luminescence intensity of a chiral complex supramolecular body according to an exemplary embodiment, depending on a wavelength for naproxen, FIG. 19 is a graph illustrating a quenching degree of a chiral complex supramolecular body according to an exemplary embodiment, depending on chirality of naproxen, and FIG. 20 is a graph illustrating a quenching degree of a chiral complex supramolecular body according to an exemplary embodiment, depending on a mixing ratio of naproxen.

Referring to FIG. 18, fluorescence intensity of the Comparative Example of the (S) type chiral complex supramolecular body of Example 2-1 ((R) type naproxen being not added) and (R) type naproxen depending on a wavelength of are illustrated. Naproxen is a chiral target compound having chirality, and may include a (S) type or a (R) type.

The Comparative Example is a material to which naproxen is not added, and it is confirmed that fluorescence intensity is greatly decreased due to the above-described quenching phenomenon, for the material to which naproxen is added, as compared with the Comparative Example. It is confirmed from the quenching phenomenon that an exemplary embodiment detects naproxen.

Referring to FIG. 19, a quenching degree of the organic electronic device according to an exemplary embodiment depending on combinations of naproxen having different chirality from each other is illustrated. The horizontal axis represents a kind of combinations of naproxen having different chirality from each other, and the vertical axis represents a relative quenching degree (Δintensity).

According to FIG. 19, when the organic electronic device is reacted with naproxen having different chirality such as a combination of (R)—(S) or (S)—(R), the quenching degree is higher. When the organic electronic device is reacted with naproxen having the same chirality such as a combination of (R)—(R) or (S)—(S), the quenching degree may be decreased by about 80% to 90%, as compared with the above-described Example. It is confirmed therefrom that the organic electronic device according to an exemplary embodiment selectively detects the chirality of naproxen.

Referring to FIG. 20, a quenching degree depending on a relative mixing ratio of naproxen of the chiral complex supramolecular body of Example 2-1 is illustrated. The horizontal axis represents a relative mixing ratio (enantiomeric excess; e.e) of (S) type or (R) type naproxen, and is defined by the following Equation 1, and the vertical axis represents a relative quenching degree (Δ Intensity) of the supramolecular body of the present Example.

e.e=(R−S)/(R+S)×100 [Equation 1]

wherein R is a content ratio of (R) type naproxen, and S is a content ratio of (S) type naproxen. For example, when the object to be sensed contains only (S) type naproxen, R=0, and the relative mixing ratio (e.e) is −100, and when the mixing ratio of (R) type and (S) type naproxen (R:S) is 1:3, the value is −50, and when (R) type and (S) type naproxen are contained identically, R=S=1, and thus, the value is 0.

According to FIG. 20, it is confirmed that the chiral complex supramolecular body according to an exemplary embodiment (Example 2-1, (S) type) selectively reacts to naproxen depending on a relative mixing ratio (e.e) of naproxen, thereby having a different quenching degree. Naproxen is a material having chirality including (S) type and (R) type, and may have the same physical and chemical properties such as taste, fragrance, boiling point and color. Therefore, a content of naproxen having chirality may be sensed, by the quenching degree, using the chiral complex supramolecular body according to an exemplary embodiment.

Specifically, as a relative mixing ratio (e.e) of naproxen is increased, that is, the content of (R) type naproxen is increased, the quenching degree is increased, and a change in fluorescence intensity is increased, whereby naproxene may be effectively sensed.

Hereinafter, the sensing characteristics for another medicine of the chiral complex supramolecular body according to an exemplary embodiment will be described, using FIG. 21.

In the present Example, description will be provided for valinol as an example of the medicine. Valinol (2-amino-3-methyl-1-butanol) is an organic compound having chirality. Valinol is also a chiral target compound having chirality like the above-described naproxen, and may include (S) type or (R) type. Valinol may be used as an intermediate material for synthesizing a medicine having chirality.

FIG. 21 is a graph illustrating a sensing degree of the chiral complex supramolecular body according to an exemplary embodiment depending on a concentration of valinol. A quencher indicated in FIG. 21 is a material causing quenching, and in the present Example, the quencher represents valinol.

Referring to FIG. 21, the quenching degree (loll) depending on the valinol concentration of about 0.1 mM to about 0.4 mM is illustrated. The quenching degree (I₀/I) is a ratio of luminescence intensity (I₀) of the Comparative Example relative to quenched luminescence intensity (I), and the higher the value is (the lower the quenched luminescence intensity is), sensing ability is better. Each test example illustrated as different figures in FIG. 21 represents sensing characteristics depending on the concentration of (R) type or (S) type valinol of the (R) type or (S) type chiral complex supramolecular body (MOF).

It is confirmed that in each test example of FIG. 21, as the concentration of valinol is increased, a sensing degree is increased. Valinol is a chiral target compound, and the higher the concentration is, the higher the quenching degree is, as described in FIGS. 19 and 20.

Here, in each test example, a variation width of the quenching degree (I₀/I) depending on the concentration of valinol is different. A variation width of the quenching degree (I₀/I) depending on the increased concentration of valinol is the highest in the Experimental Example in which the (R) type chiral supramolecular body senses (S) type valinol, and the lowest in the Experimental Example in which the (S) type chiral supramolecular body senses (S) type valinol. As such, a chiral quencher, which is a medicine such as valinol in the present Example may be effectively sensed, using the fact that the quenching degree (I₀/I) is different depending on a combination of the supramolecular body and a quencher having different chirality.

Meanwhile, when the concentration of valinol is constant, sensing ability of the (R) type supremolecular body (MOF) for the (S) type valinol is the best. Next, the sensing ability is excellent in the order of (R) type valinol of the (R) type supremolecular body (MOF), (R) type valinol of the (S) type supramolecular body (MOF), and (S) type valinol of the (S) type supramolecular body (MOF). This trend is significant when the concentration of valinol is about 0.2 mM or more. When the concentration of valinol is less than about 0.2 mM, sensing ability according to each Example may be almost similar.

As seen from FIGS. 18 to 21, the chiral complex supramolecular body according to an exemplary embodiment may effectively sense medicines such as naproxen and valinol which are chiral target compounds by photoluminescence (PL) analysis. As such, the medicines having chirality is selectively sensed, thereby separating the medicine from another material having a side effect in the enantiomers.

Hereinafter, referring to FIGS. 22 to 25, the sensing characteristics of the organic electronic device according to an exemplary embodiment for chemical gas will be described. FIGS. 22 and 23 are graphs illustrating electrical conductivity change and reaction sensitivity of a chiral complex supramolecular body according to an exemplary embodiment, when exposed to chemical gas, respectively, FIG. 24 is a graph illustrating a result of real-time sensing of a chiral complex supramolecular body according to an exemplary embodiment, depending on a concentration of aniline, and FIG. 25 is a graph illustrating a result of powder X-ray diffraction (PXRD) analysis of a chiral complex supramolecular body according to an exemplary embodiment before and after adsorption of chemical gas.

Referring to FIG. 22, change in current (pA) depending on applied voltage (V) to each chemical gas of the organic electronic device according to Example 3-3 (including a racemic type supramolecular body) is illustrated. The Comparative Example (no exposure) in which the chiral complex supramolecular body is not exposed to any chemical gas is also illustrated together. In the present Example, the chemical gas may include non-polar dichloromethane and n-hexane, and polar ethanol, methanol and aniline (C₆H₅NH₂).

The organic electronic device according to an exemplary embodiment does not show change in current to non-polar chemical gas, but it is confirmed that as the polarity of the chemical gas is higher, change in current is bigger. That is, the organic electronic device according to an exemplary embodiment may sense polar chemical gas, and shows bigger change in electrical conductivity to chemical gas having high polarity.

Referring to FIG. 23, the conductivity change and reaction sensitivity of the organic electronic device according to an exemplary embodiment to the above-described chemical gases are illustrated. The left vertical axis is a change in conductivity (conductance; expressed as G in FIG. 23), the change in conductivity (ΔG/G₀) represents a ratio of conductivity change (ΔG) after exposure to chemical gas relative to conductivity (G₀) before exposure to chemical gas. The right vertical axis represents sensitivity, and the unit is pA/ppm, and may refer to sensitivity to change in electrical conductivity as described in FIG. 22.

It is confirmed that the change in conductivity (ΔG/G₀) hardly appears when sensing dichloromethane and n-hexane which are non-polar gas, and has a significant value when sensing other polar gases.

Particularly, the change in conductivity (ΔG/G₀) is highest in the case of aniline having highest polarity among the chemical gases of the present Example, and is high in the order of methanol and ethanol. The reaction sensitivity is about 0.1 to 1 pA/ppm in the case of anilines, which is the highest, and about 0.0001 pA/ppm in the case of methanol and ethanol, which is similar to each other. That is, sensing is more sensitive as the chemical gas has higher polarity.

Referring to FIG. 24, the results of real-time sensing for aniline depending on time (s) of the organic electronic device according to Example 3 are illustrated. It is confirmed that the organic electronic device according to Example 3 detects aniline having a highest reaction sensitivity in FIG. 23 up to about 50 ppm at the minimum, in real time.

Referring to FIG. 25, the characteristics of the crystal structure of the chiral complex supramolecular body according to Example 2-3 by powder X-ray diffraction (PXRD) analysis are illustrated. The powder X-ray diffraction (PXRD) analysis method is an example of a method of analyzing the crystal structure, and analyzes the crystal structure of a material using the characteristic in which X-ray is irradiated on the material so that the X-ray is diffracted along the direction of a lattice plane of a crystal particle. The crystal structure of a certain material can be identified in the form of the powder X-ray diffraction (PXRD) analysis graph.

According to FIG. 25, a powder X-ray diffraction (PXRD) graph of the supramolecular bodies of Example 2-3 exposed to the Comparative Example, ethanol, and aniline is illustrated. In all of the three Examples, the supramolecular bodies have the same X-ray intensity at the same bragg angle (Θ), and thus, it is found that all of the three Examples have the same crystal structure.

As such, the chiral complex supramolecular body according to an exemplary embodiment may have the same crystal structure as before exposure, even after being exposed to target chemical gas. That is to say, it is confirmed that an increase in electrical conductivity as seen from FIGS. 22 and 23 is not caused by the collapse of the crystal structure of the supramolecular body.

Hereinafter, referring to FIGS. 26 and 27, the sensing characteristics of the chiral complex supramolecular body according to an exemplary embodiment for trimethylamine (TEA) will be described by change in electrical conductivity. FIGS. 26 and 27 are graphs illustrating voltage-current curves of organic electronic devices including (R) type and (S) type chiral complex supramolecular bodies, respectively.

Referring to FIG. 26 and FIG. 27, change in current of the organic electronic device according to an exemplary embodiment, in the Comparative Example (no exposure), the Experimental Example exposed to trimethylamine (TEA exposure), and the Experimental Example with trimethylamine removed again (after degassing), is illustrated, respectively. The horizontal axis represents voltage applied to the drain electrode of the organic electronic device according to an exemplary embodiment, and the vertical axis represents current flowing in the drain electrode. The drain electrode may be the first electrode 41 or the second electrode 42, described in FIGS. 4 to 6. As the voltage applied to the organic electronic device according to an exemplary embodiment is increased, following current is also increased.

Referring to FIG. 26, voltage-current curves (I-V curve) to the test example when the organic electronic device by Example 3-2 ((S) type) is not exposed to trimethylamine (TEA) (No exposure), immediately before the organic electronic device is exposed to TEA (TEA exposure), and immediately after TEA is removed (After degassing) are illustrated.

Immediately when voltage of about 0 V to 50 V is applied after the organic electronic device by Example 3-2 is exposed to trimethylamine (TEA), it is confirmed that current of about 0 pA to 10 pA flows. Particularly, when voltage of about 40 V to 50V is applied, current of about 8 pA to 10 pA flows, and the maximum current value may be about 10 pA.

When supply of trimethylamine (TEA) to the organic electronic device by Example 3-2 is stopped, and after 10 seconds, trimethylamine (TEA) is removed (degassing), the current hardly flows, as before exposure. That is, when the organic electronic device according to an exemplary embodiment is exposed to trimethylamine (TEA), sensing trimethylamine (TEA) may be confirmed by flowing current.

Referring to FIG. 27, voltage-current curves of the organic electronic device by Example 3-1 ((R) type) are illustrated. Hereinafter, a difference thereof from FIG. 26 will be mainly described.

When voltage of about 0 V to 50 V is applied immediately after the organic electronic device by Example 3-1 is exposed to trimethylamine (TEA), it is confirmed that current of about 0 pA to 11 pA flows. Particularly, when voltage of about 40 V to 50 V is applied, current of about 9 pA to 11 pA flows, and the maximum current value may be about 11 pA. As compared with Example 3-2 ((S) type) of FIG. 26, the maximum current value is increased in the same voltage range.

As in FIG. 26, when supply of trimethylamine (TEA) to the organic electronic device by Example 3-1 is stopped, and trimethylamine (TEA) is again removed (degassing) after 10 seconds, the current hardly flows as before exposure. However, as compared with FIG. 26, it is confirmed that the current flowing when trimethylamine (TEA) is removed is minutely increased.

As such, when the chiral complex supramolecular body according to an exemplary embodiment is exposed to trimethylamine (TEA), sensing trimethylamine (TEA) may be confirmed by flowing current, as compared with the Comparative Example, and the case of degassing.

As described above, the chiral complex supramolecular body according to an exemplary embodiment may effectively sense medicines such as naproxen and valinol which are chiral target compounds by photoluminescence (PL) analysis. The medicine having chirality is selectively detected, thereby separating the medicine from another material having a side effect in the enantiomers, so that a potential risk may be prevented.

In addition, the chiral complex supramolecular body according to an exemplary embodiment may effectively sense light, polar chemical gas, and the like, as well as various amine compounds including nitrogen, by photoluminescence (PL) analysis.

The organic electronic device according to an exemplary embodiment includes the active layer including the chiral complex supramolecular body as described above, thereby sensing various chiral polymers. The entire organic electronic device system secures chirality by the supramolecular body in which the chiral organic ligand and a metal ion are coordinated with each other, thereby being utilized as an organic sensor which detects various elements having chirality with high performance.

In addition, according to an exemplary embodiment, misarranged orientation which is disadvantageous in charge transfer is minimized, thereby providing the organic electronic device having greatly improved photosensitivity and electrical characteristics.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

<Description of symbols>

| | |
|---|---|
| 10: Substrate | 20: Gate insulation film |
| 30: Surface modified layer | 40: Electrode |
| 41, 42: First and second electrodes | 50: Active layer |

1. A chiral organic ligand which is any one selected from the group consisting of organic ligands represented by the following Chemical Formula 1 and Chemical Formula 2: 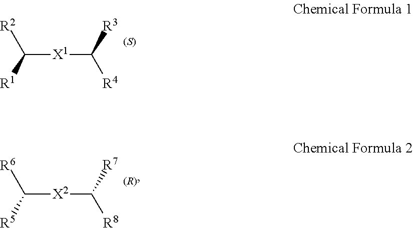
wherein
X¹ and X² are independently of each other 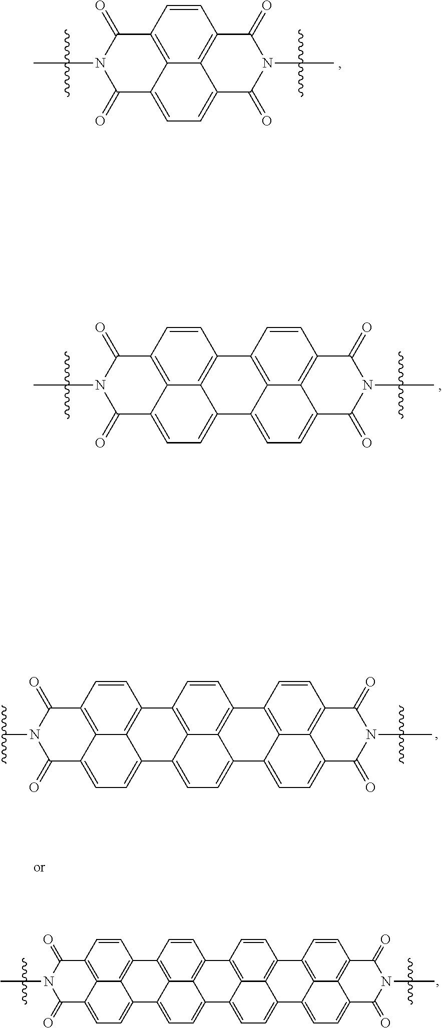 [SMILES: *N1C(=O)c2ccc3c4c(ccc(c24)C1=O)C(=O)N(*)C3=O ; *N1C(=O)c2ccc3c4ccc5c6c(ccc(c7ccc(c2c37)C1=O)c64)C(=O)N(*)C5=O ; *N1C(=O)c2ccc3c4ccc5c6ccc7c8c(ccc(c9ccc(c%10ccc(c2c3%10)C1=O)c4c59)c86)C(=O)N(*)C7=O ; *N1C(=O)c2ccc3c4ccc5c6ccc7c8ccc9c%10c(ccc(c%11ccc(c%12ccc(c%13ccc(c2c3%13)C1=O)c4c5%12)c6c7%11)c%108)C(=O)N(*)C9=O]
R¹, R³, R⁵, and R⁷ are independently of one another any one selected from the group consisting of a carboxy group, a hydroxyl group, an amino group, a sulfhydryl group, and a phosphate, and
R², R⁴, R⁶, and R⁸ are independently of one another any one selected from the group consisting of C1 to C5 alkyl groups and C1 to C5 aryl groups.

2. The chiral organic ligand of claim 1, wherein:
R¹, R³, R⁵, and R⁷ are independently of one another any one selected from the group consisting of a carboxy group, a hydroxyl group, and an amino group, and
R², R⁴, R⁶, and R⁸ are independently of one another any one selected from the group consisting of C1 to C3 alkyl groups and C1 to C3 aryl groups.

3. The chiral organic ligand of claim 2, wherein:
R¹, R³, R⁵, and R⁷ are a carboxy group, and
R², R⁴, R⁶, and R⁸ are a methyl group.

4. A chiral complex supramolecular body comprising: a chiral organic ligand which is any one selected from the group consisting of organic ligands represented by the following Chemical Formula 1 and Chemical Formula 2; and
a metal ion coordinated with the organic ligand,
wherein the metal ion is any one selected from the group consisting of zinc, copper, nickel, cadmium, iron, chromium, cobalt, calcium, magnesium, manganese, silver, and gold: 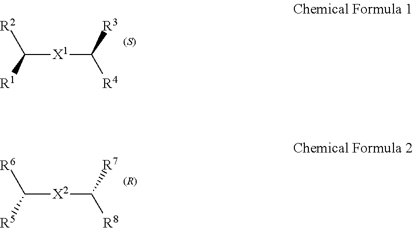
wherein
X¹ and X² are independently of each other 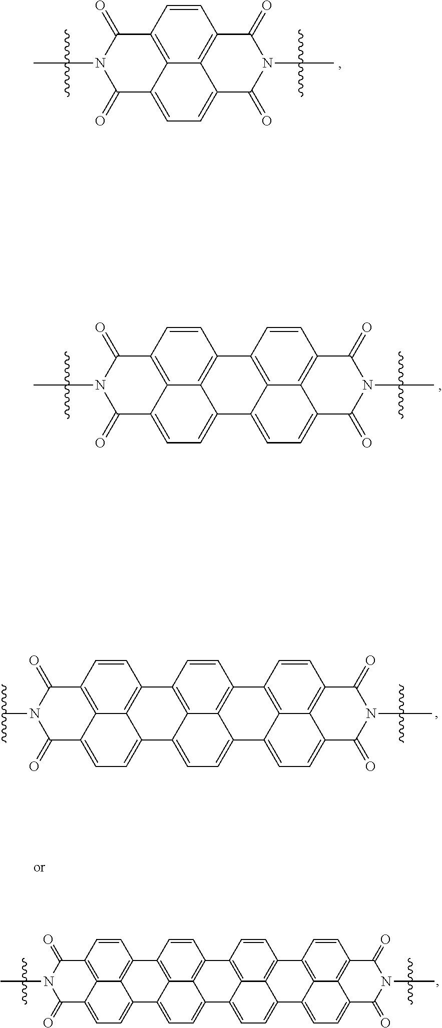 [SMILES: *N1C(=O)c2ccc3c4c(ccc(c24)C1=O)C(=O)N(*)C3=O ; *N1C(=O)c2ccc3c4ccc5c6c(ccc(c7ccc(c2c37)C1=O)c64)C(=O)N(*)C5=O ; *N1C(=O)c2ccc3c4ccc5c6ccc7c8c(ccc(c9ccc(c%10ccc(c2c3%10)C1=O)c4c59)c86)C(=O)N(*)C7=O ; *N1C(=O)c2ccc3c4ccc5c6ccc7c8ccc9c%10c(ccc(c%11ccc(c%12ccc(c%13ccc(c2c3%13)C1=O)c4c5%12)c6c7%11)c%108)C(=O)N(*)C9=O]
R¹, R³, R⁵, and R⁷ are independently of one another any one selected from the group consisting of a carboxy group, a hydroxyl group, an amino group, a sulfhydryl group, and a phosphate, and
R², R⁴, R⁶, and R⁸ are independently of one another any one selected from the group consisting of C1 to C5 alkyl groups and C1 to C5 aryl groups.

5. The chiral complex supramolecular body of claim 4, wherein:
a single crystal of the chiral complex supramolecular body has a ribbon shape.

6. An organic electronic device comprising: a substrate;
an electrode disposed on the substrate; and
an active layer including a chiral complex supramolecular body, disposed on the electrode;
wherein the chiral complex supramolecular body includes
a chiral organic ligand which is any one selected from the group consisting of organic ligands represented by the following Chemical Formula 1 and Chemical Formula 2; and
a metal ion coordinated with the organic ligand;
and the metal ion is any one selected from the group consisting of zinc, copper, nickel, cadmium, iron, chromium, cobalt, calcium, magnesium, manganese, silver, and gold: 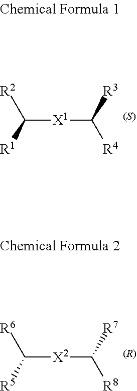
wherein
X¹ and X² are independently of each other 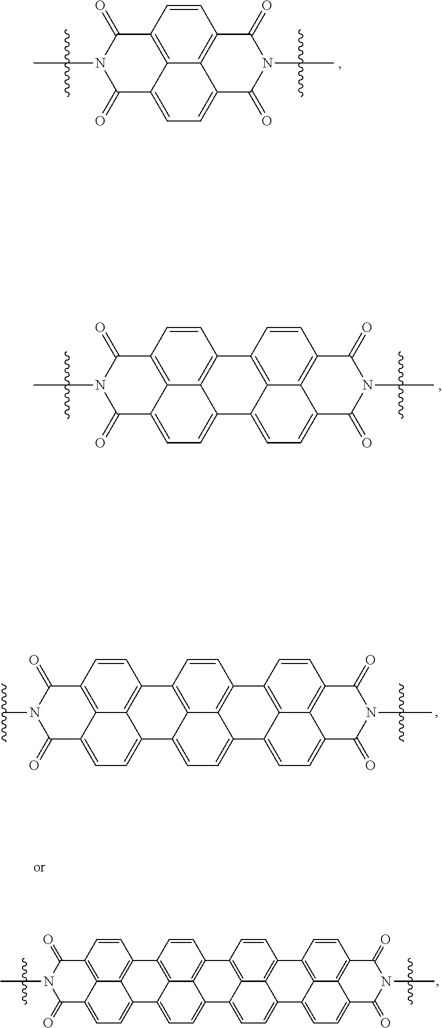 [SMILES: *N1C(=O)c2ccc3c4c(ccc(c24)C1=O)C(=O)N(*)C3=O ; *N1C(=O)c2ccc3c4ccc5c6c(ccc(c7ccc(c2c37)C1=O)c64)C(=O)N(*)C5=O ; *N1C(=O)c2ccc3c4ccc5c6ccc7c8c(ccc(c9ccc(c%10ccc(c2c3%10)C1=O)c4c59)c86)C(=O)N(*)C7=O ; *N1C(=O)c2ccc3c4ccc5c6ccc7c8ccc9c%10c(ccc(c%11ccc(c%12ccc(c%13ccc(c2c3%13)C1=O)c4c5%12)c6c7%11)c%108)C(=O)N(*)C9=O]
R¹, R³, R⁵, and R⁷ are independently of one another any one selected from the group consisting of a carboxy group, a hydroxyl group, an amino group, a sulfhydryl group, and a phosphate, and
R², R⁴, R⁶, and R⁸ are independently of one another any one selected from the group consisting of C1 to C5 alkyl groups and C1 to C5 aryl groups.

7. The organic electronic device of claim 6, wherein:
the electrode includes a first electrode and a second electrode, and
the active layer is disposed to cross the first electrode and the second electrode.

8. The organic electronic device of claim 6, further comprising:
a surface modified layer disposed between the substrate and the active layer,
wherein the surface modified layer includes a self-assembled monolayer (SAM), and
the self-assembled monolayer (SAM) is formed by surface-treating the substrate with any one selected from the group consisting of n-octadecyltrimethoxysilane, n-octadecyltrichlorosilane, n-octyltrichlorosilane, n-octylphosphate, and n-octadecylphosphate.

9. The organic electronic device of claim 6, wherein:
the organic electronic device is one selected from the group consisting of an organic sensor, an organic transistor, an organic light emitting diode, and an organic solar cell.

10. The organic electronic device of claim 9, wherein:
the organic electronic device is the organic sensor, and
the organic sensor detects one or more selected from the group consisting of light, chemical gas, and a medicine.

11. The organic electronic device of claim 10, wherein:
as a concentration of the light, chemical gas, or medicine is increased, the organic sensor has decreased luminescence intensity by photoluminescence (PL).

12. The organic electronic device of claim 11, wherein:
the luminescence by the photoluminescence (PL) is fluorescence.

13. The organic electronic device of claim 10, wherein:
the medicine includes naproxen, and
as a concentration of the naproxen is increased, luminescence intensity by photoluminescence (PL) is decreased.

14. The organic electronic device of claim 10, wherein:
the medicine includes valinol, and
as a concentration of the valinol is increased, luminescence intensity by photoluminescence (PL) is decreased.

15. The organic electronic device of claim 10, wherein:
the chemical gas includes an amine compound, alcohol and a polar solvent.

16. The organic electronic device of claim 15, wherein:
the amine compound includes at least one of hydrazine, trimethylamine (TEA), and phenylethylamine (PEA).

17. The organic electronic device of claim 10, wherein:
the chiral complex supramolecular body has the same crystal structure before and after exposure to the chemical gas.

18. A manufacturing method of an organic electronic device, comprising: (a) providing a substrate;
(b) forming an electrode on the substrate; and
(c) forming an active layer including a chiral complex supramolecular body on the electrode;
wherein the chiral complex supramolecular body includes
a chiral organic ligand which is any one selected from the group consisting of organic ligands represented by the following Chemical Formula 1 and Chemical Formula 2; and
a metal ion coordinated with the organic ligand, and
the metal ion is any one selected from the group consisting of zinc, copper, nickel, cadmium, iron, chromium, cobalt, calcium, magnesium, manganese, silver, and gold: 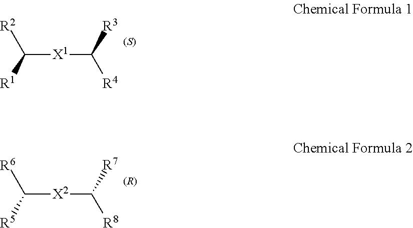
wherein
X¹ and X² are independently of each other 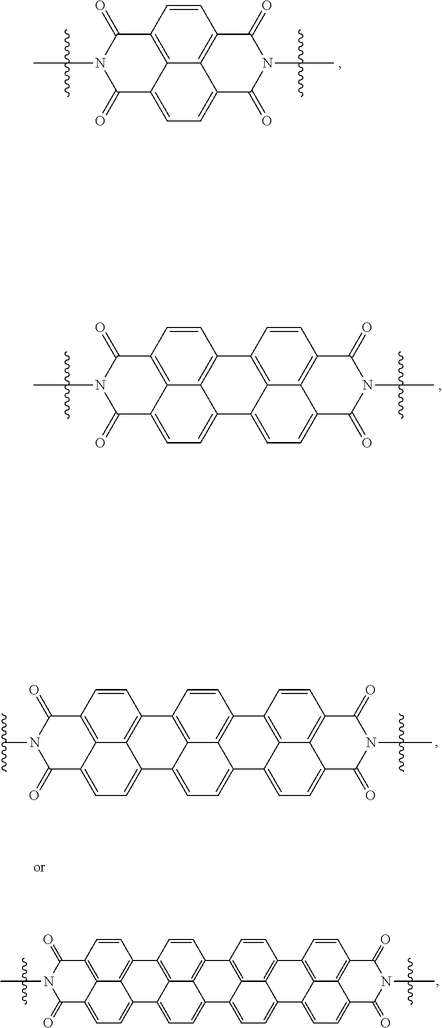 [SMILES: *N1C(=O)c2ccc3c4c(ccc(c24)C1=O)C(=O)N(*)C3=O ; *N1C(=O)c2ccc3c4ccc5c6c(ccc(c7ccc(c2c37)C1=O)c64)C(=O)N(*)C5=O ; *N1C(=O)c2ccc3c4ccc5c6ccc7c8c(ccc(c9ccc(c%10ccc(c2c3%10)C1=O)c4c59)c86)C(=O)N(*)C7=O ; *N1C(=O)c2ccc3c4ccc5c6ccc7c8ccc9c%10c(ccc(c%11ccc(c%12ccc(c%13ccc(c2c3%13)C1=O)c4c5%12)c6c7%11)c%108)C(=O)N(*)C9=O]
R¹, R³, R⁵, and R⁷ are independently of one another any one selected from the group consisting of a carboxy group, a hydroxyl group, an amino group, a sulfhydryl group, and a phosphate, and
R², R⁴, R⁶, and R⁸ are independently of one another any one selected from the group consisting of C1 to C5 alkyl groups and C1 to C5 aryl groups.

19. The manufacturing method of claim 18, further comprising:
after the process of (a),
(a′) oxidation-treating one surface of the substrate to manufacture the substrate including a hydroxyl group (—OH) on the one surface.

20. The manufacturing method of claim 19, further comprising:
after the process of (a′),
(a″) forming a self-assembled monolayer (SAM) on one surface of the substrate,
wherein the self-assembled monolayer (SAM) is formed by after oxidation-treating the one substrate, treating the surface with any one selected from the group consisting of n-octadecyltrimethoxysilane (n-octadecyltrimethoxysilane), n-octadecyltrichlorosilane, n-octyltrichlorosilane, n-octylphosphate, and n-octadecylphosphate.
